(19) United States
(12) Patent Application Publication
(10) Pub. No.: US 2024/0349562 A1
(43) Pub. Date: Oct. 17, 2024

(54) TILED DISPLAY PANEL AND DISPLAY DEVICE

(71) Applicant: Shanghai Tianma Microelectronics Co., Ltd., Shanghai (CN)

(72) Inventors: Shouzheng WU, Shanghai (CN); Yuhui LAI, Shanghai (CN); Yongxin HE, Shanghai (CN); Jiaxian LIU, Shanghai (CN); Jujian FU, Shanghai (CN); Yuan DING, Shanghai (CN)

(73) Assignee: Shanghai Tianma Microelectronics Co., Ltd., Shanghai (CN)

(21) Appl. No.: 18/753,652

(22) Filed: Jun. 25, 2024

(30) Foreign Application Priority Data
Dec. 29, 2023 (CN) 202311872882.6

(51) Int. Cl. H10K 59/18

(52) U.S. Cl. CPC H10K 59/18

(57) ABSTRACT

Provided are a tiled display panel and a display device. The tiled display panel includes a transparent substrate and at least two display subpanels. The at least two display subpanels are disposed in at least two tiled regions of the transparent substrate respectively. A first alignment pattern on the transparent substrate includes at least two first sub-patterns. The at least two first sub-patterns are disposed in the at least two tiled regions respectively. A first sub-pattern includes a hollowed-out region. A second alignment pattern on a display subpanel includes at least two second sub-patterns. The shape of a second sub-pattern is the same as the shape of the hollowed-out region. The vertical projection of the second sub-pattern on the transparent substrate is located in the hollowed-out region.

### CROSS-REFERENCE TO RELATED APPLICATION

This application claims priority to Chinese patent application No. 202311872882.6 filed with the China National Intellectual Property Administration (CNIPA) on Dec. 29, 2023, the disclosure of which is incorporated herein by reference in its entirety.

### TECHNICAL FIELD

The present disclosure relates to the field of display technology and, in particular, to a tiled display panel and a display device.

### BACKGROUND

Since display panels are applied in more and more scenarios, the size of the existing monolithic display panel cannot satisfy the requirement of a large display area scenario. To solve this problem, multiple display panels need to be tiled to form a tiled display panel that is able to implement large-size image display.

At present, a tiled display panel is generally formed by manually tiling and assembling display panels. Since a manual tiling method has certain limitations in tiling accuracy, as the pixel spacing of display panels becomes smaller and smaller, a tiling effect such as pixel edge alignment cannot be ensured in the manual tiling method, and a tiling application scenario of small pixel spacing and high resolution cannot be satisfied.

### SUMMARY

The present disclosure provides a tiled display panel and a display device to implement high-precision alignment and tiling of the display panel and obtain a better tiling effect.

Embodiments of the present disclosure provide a tiled display panel. The tiled display panel includes a transparent substrate and at least two display subpanels.

The transparent substrate includes at least two tiled regions. The at least two display subpanels are disposed in the at least two tiled regions respectively.

The transparent substrate further includes a first alignment pattern. The first alignment pattern includes at least two first sub-patterns. The at least two first sub-patterns are disposed in the at least two tiled regions respectively.

A first sub-pattern includes a hollowed-out region.

A display subpanel includes a second alignment pattern. The second alignment pattern includes at least two second sub-patterns. The shape of a second sub-pattern is the same as the shape of the hollowed-out region. The vertical projection of the second sub-pattern on the transparent substrate is located in the hollowed-out region.

Embodiments of the present disclosure provide a display device. The display device includes the tiled display panel described above.

In the tiled display panel and the display device provided by embodiments of the present disclosure, the transparent substrate and at least two display subpanels are included. The transparent substrate includes at least two tiled regions. The at least two display subpanels are disposed in the at least two tiled regions respectively. In this manner, the structural strength and flatness of the whole tiled display panel can be improved. At the same time, the transparent substrate also includes a first alignment pattern. The first alignment pattern includes at least two first sub-patterns. The at least two first sub-patterns are disposed in the at least two tiled regions respectively. The first sub-pattern includes a hollowed-out region. The tiled display panel includes a second alignment pattern. The second alignment pattern includes at least two second sub-patterns. The shape of the second sub-pattern is the same as the shape of the hollowed-out region. When the display subpanel is aligned and tiled on the transparent substrate, the vertical projection of the second sub-pattern on the transparent substrate is located in the hollowed-out region.

It is to be understood that the contents described in this part are not intended to identify key or important features of the embodiments of the present disclosure and are not intended to limit the scope of the present disclosure. Other features of the present disclosure become readily understood through the description hereinafter.

### BRIEF DESCRIPTION OF DRAWINGS

To illustrate solutions in embodiments of the present disclosure more clearly, the accompanying drawings used in description of the embodiments may be briefly described below.

Apparently, the accompanying drawings described below illustrate part of embodiments of the present disclosure, and those of ordinary skill in the art may obtain other accompanying drawings based on the accompanying drawings described below on the premise that no creative work is done.

FIG. 1 is a diagram illustrating the structure of a tiled display panel according to an embodiment of the present disclosure.

FIG. 2 is an enlarged view illustrating the structure of part A of FIG. 1.

FIG. 3 is a diagram illustrating the structure of a transparent substrate according to an embodiment of the present disclosure.

FIG. 4 is a diagram illustrating the structure of a first alignment pattern according to an embodiment of the present disclosure.

FIG. 5 is a diagram illustrating the structure of a display subpanel according to an embodiment of the present disclosure.

FIG. 6 is a sectional view taken along direction B-B′ in FIG. 5.

FIG. 7 is a diagram illustrating the structure of a second alignment pattern according to an embodiment of the present disclosure.

FIG. 8 is a partial view illustrating the structure of a tiled display panel according to an embodiment of the present disclosure.

FIG. 9 is a partial sectional view illustrating the structure of a tiled display panel according to an embodiment of the present disclosure.

FIG. 10 is a diagram illustrating the structure of another tiled display panel according to an embodiment of the present disclosure.

FIG. 11 is an enlarged view illustrating the structure of part C of FIG. 10.

FIG. 12 is a diagram illustrating the structure of another transparent substrate according to an embodiment of the present disclosure.

FIG. 13 is a diagram illustrating the structure of another first alignment pattern according to an embodiment of the present disclosure.

FIG. 14 is a diagram illustrating the structure of another display subpanel according to an embodiment of the present disclosure.

FIG. 15 is a diagram illustrating the structure of another second alignment pattern according to an embodiment of the present disclosure.

FIG. 16 is a diagram illustrating the structure of another display subpanel according to an embodiment of the present disclosure.

FIG. 17 is a diagram illustrating the structure of another display subpanel according to an embodiment of the present disclosure.

FIG. 18 is a diagram illustrating the structure of another tiled display panel according to an embodiment of the present disclosure.

FIG. 19 is an enlarged view illustrating the structure of part D of FIG. 18.

FIG. 20 is a diagram illustrating the structure of another transparent substrate according to an embodiment of the present disclosure.

FIG. 21 is a diagram illustrating the structure of a first display subpanel according to an embodiment of the present disclosure.

FIG. 22 is a diagram illustrating the structure of a second display subpanel according to an embodiment of the present disclosure.

FIG. 23 is a diagram illustrating the structure of another tiled display panel according to an embodiment of the present disclosure.

FIG. 24 is an enlarged view illustrating the structure of part E of FIG. 23.

FIG. 25 is a diagram illustrating the structure of another transparent substrate according to an embodiment of the present disclosure.

FIG. 26 is a diagram illustrating the structure of another display subpanel according to an embodiment of the present disclosure.

FIG. 27 is a diagram illustrating the structure of another tiled display panel according to an embodiment of the present disclosure.

FIG. 28 is a diagram illustrating the structure of another tiled display panel according to an embodiment of the present disclosure.

FIG. 29 is a diagram illustrating the structure of another tiled display panel according to an embodiment of the present disclosure.

FIG. 30 is a sectional view taken along direction F-F′ in FIG. 29.

FIG. 31 is a diagram illustrating the structure of another tiled display panel according to an embodiment of the present disclosure.

FIG. 32 is a diagram illustrating the structure of another tiled display panel according to an embodiment of the present disclosure.

FIG. 33 is a diagram illustrating the structure of another transparent substrate according to an embodiment of the present disclosure.

FIG. 34 is a diagram illustrating the structure of another tiled display panel according to an embodiment of the present disclosure.

FIG. 35 is a sectional view taken along direction G-G′ in FIG. 34.

FIG. 36 is a diagram illustrating the structure of another transparent substrate according to an embodiment of the present disclosure.

FIG. 37 is a diagram illustrating the structure of another tiled display panel according to an embodiment of the present disclosure.

FIG. 38 is a sectional view illustrating the structure of a tiled display panel according to an embodiment of the present disclosure.

FIG. 39 is a sectional view illustrating the structure of another tiled display panel according to an embodiment of the present disclosure.

FIG. 40 is a sectional view illustrating the structure of another tiled display panel according to an embodiment of the present disclosure.

FIGS. 41 to 47 are partial views illustrating the structure of a tiled display panel according to an embodiment of the present disclosure.

FIG. 48 is a diagram illustrating the structure of a display device according to an embodiment of the present disclosure.

### DETAILED DESCRIPTION

The solutions in embodiments of the present disclosure are described clearly and completely in conjunction with the drawings in the embodiments of the present disclosure from which the solutions may be better understood by those skilled in the art. Apparently, the embodiments described below are part, not all, of the embodiments of the present disclosure. Based on the embodiments described herein, all other embodiments obtained by those skilled in the art on the premise that no creative work is done are within the scope of the present disclosure.

It is to be noted that the terms “first”, “second” and the like in the description, claims and drawings of the present disclosure are used to distinguish between similar objects and are not necessarily used to describe a particular order or sequence. It should be understood that the data used in this way is interchangeable where appropriate so that the embodiments of the present disclosure described herein may also be implemented in a sequence not illustrated or described herein. In addition, the terms “comprising”, “including” or any other variations thereof herein are intended to encompass a non-exclusive inclusion. For example, a process, method, system, product or device that includes a series of steps or elements not only includes the expressly listed steps or elements but may also include other steps or elements that are not expressly listed or are inherent to such process, method, system, product or device.

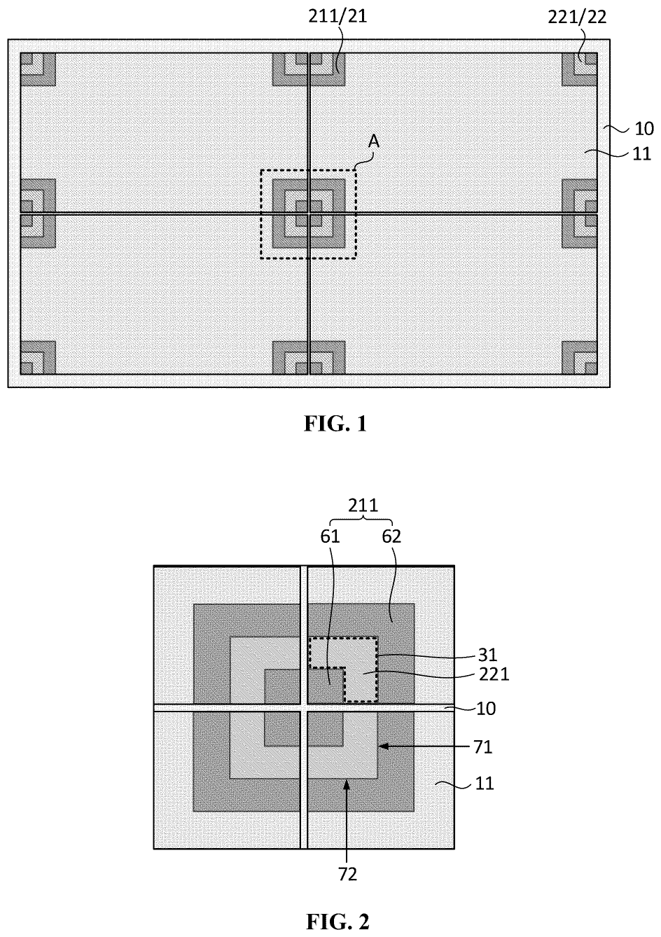

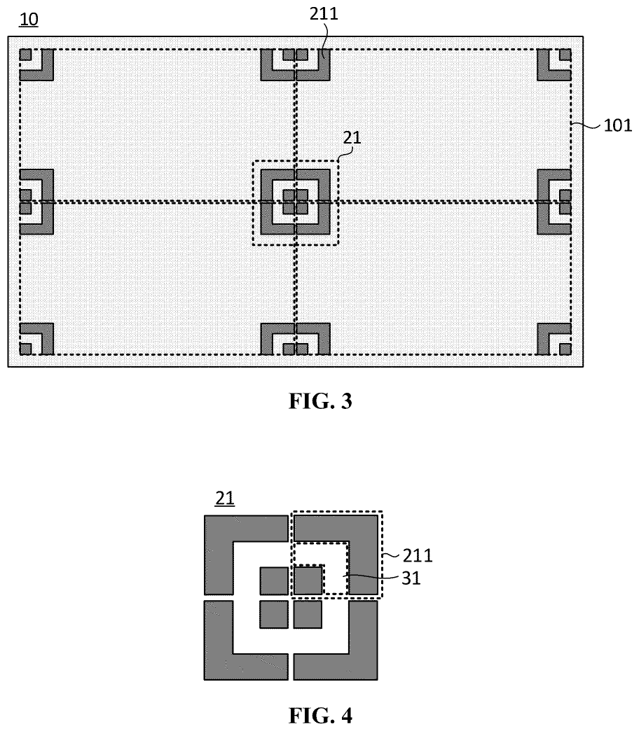

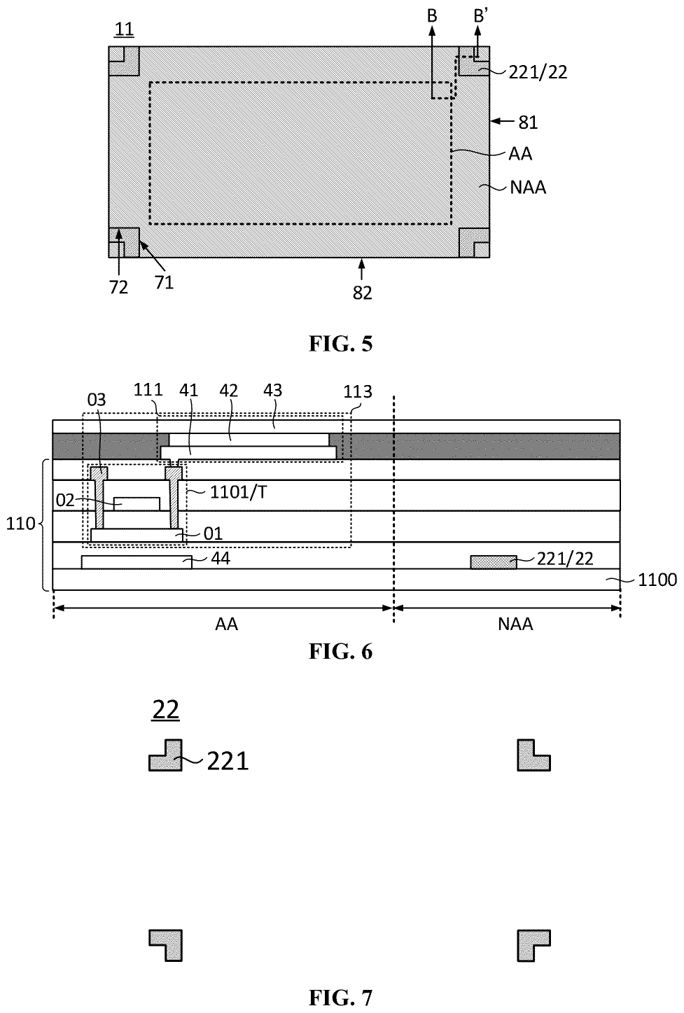

FIG. 1 is a diagram illustrating the structure of a tiled display panel according to an embodiment of the present disclosure. FIG. 2 is an enlarged view illustrating the structure of part A of FIG. 1. FIG. 3 is a diagram illustrating the structure of a transparent substrate according to an embodiment of the present disclosure. FIG. 4 is a diagram illustrating the structure of a first alignment pattern according to an embodiment of the present disclosure. FIG. 5 is a diagram illustrating the structure of a display subpanel according to an embodiment of the present disclosure. FIG. 6 is a sectional view taken along direction B-B′ in FIG. 5. FIG. 7 is a diagram illustrating the structure of a second alignment pattern according to an embodiment of the present disclosure. As shown in FIGS. 1 to 7, the tiled display panel of this embodiment of the present disclosure includes a transparent substrate 10 and at least two display subpanels 11. The transparent substrate 10 includes at least two tiled regions 101. The at least two display subpanels 11 are disposed in the at least two tiled regions 101 respectively. The transparent substrate 10 also includes a first alignment pattern 21. The first alignment pattern 21 includes at least two first sub-patterns 211. The at least two first sub-patterns 211 are disposed in the at least two tiled regions 101 respectively. A first sub-pattern 211 includes a hollowed-out region 31. A display subpanel 11 includes a second alignment pattern 22. The second alignment pattern 22 includes at least two second sub-patterns 221. The shape of the second sub-pattern 221 is the same as the shape of the hollowed-out region 31. The vertical projection of the second sub-pattern 221 on the transparent substrate 10 is located in the hollowed-out region 31.

In an embodiment, as shown in FIGS. 1 to 7, the display subpanel 11 has a display function. The tiled display panel is formed by tiling at least two display subpanels 11 to implement the large-size image display effect of the tiled display panel.

The display subpanel 11 may include a liquid crystal display (LCD) panel, an organic light-emitting diode (OLED) display panel, a light-emitting diode (LED) display panel, a sub-millimeter light-emitting diode (mini LED) display panel, or a micron light-emitting diode (micro LED) display panel. The type of the display subpanel 11 is not specifically limited in the embodiment of the present disclosure.

For example, as shown in FIGS. 5 and 6, description is given by using an example in which the display subpanel 11 is an OLED display panel. The display subpanel 11 may include an array substrate 110 and multiple pixel units 111 arranged in an array. The array substrate 110 includes a base substrate 1100 and multiple driver circuits 1101 disposed on a side of the base substrate 1100, which is not limited thereto.

In an embodiment, with continued reference to FIGS. 1 to 7, the tiled display panel also includes a transparent substrate 10. The transparent substrate 10 is used as a support structure of the display subpanel 11. The size or area of the transparent substrate 10 may be several times that of the display subpanel 11, so that the transparent substrate 10 is able to allow multiple display subpanels 11 to be tiled on the surface of the transparent substrate 10. In this embodiment, multiple display subpanels 11 are tiled on the same transparent substrate 10. In this manner, the structural strength and flatness of the whole tiled display panel can be improved.

In an embodiment, as shown in FIGS. 1 to 7, the transparent substrate 10 is divided into multiple tiled regions 101. Each tiled region 101 is correspondingly provided with a display subpanel 11. The transparent substrate 10 is provided with a first alignment pattern 21. The first alignment pattern 21 includes at least two first sub-patterns 211. Different first sub-patterns 211 in the same first alignment pattern 21 are disposed in different tiled regions 101 respectively, that is, each first sub-pattern 211 in the same first alignment pattern 21 is correspondingly disposed in a different tiled region 101.

In an embodiment, as shown in FIGS. 1 to 7, the display subpanel 11 is provided with a second alignment pattern 22. The second alignment pattern 22 includes at least two second sub-patterns 221. When the display subpanel 11 is tiled on the transparent substrate 10, the first sub-pattern 211 on the transparent substrate 10 and the second sub-pattern 221 on the display subpanel 11 match each other.

For example, in the process in which the display subpanel 11 is tiled on the transparent substrate 10, the first alignment pattern 21 on the transparent substrate 10 and the second alignment pattern 22 on the display subpanel 11 may be picked up by a camera, and then, the relative position between the transparent substrate 10 and the display subpanel 11 is guided and adjusted according to the matching situation between the first alignment pattern 21 and the second alignment pattern 22. In this manner, the first alignment pattern 21 on the transparent substrate 10 and the second alignment pattern 22 on the display subpanel 11 match each other, thereby completing adhering and tiling of the display subpanel 11 on the transparent substrate 10.

The transparent substrate 10 is a transparent and rigid platy structure and may be made of a material such as glass, quartz, or plastic. For example, in this embodiment, the transparent substrate 10 may be a glass substrate. In the process in which the display subpanels 11 are tiled on the transparent substrate 10, the camera may be disposed on a side of the transparent substrate 10 to acquire the images of the second alignment patterns 22 on the display subpanels 11 through the transparent substrate 10.

In an embodiment, with continued reference to FIGS. 1 to 7, the number of first sub-patterns 211 in any tiled region 101 on the transparent substrate 10 is the same as the number of second sub-patterns 221 adhered to the display subpanel 11 of the tiled region 101. In the process in which the display subpanel 11 is tiled on the transparent substrate 10, the first sub-patterns 211 in the same tiled region 101 correspondingly match the second sub-patterns 221 adhered to the display subpanel 11 of the tiled region 101 in a one-to-one manner. A first sub-pattern 211 includes a hollowed-out region 31. The shape of a second sub-pattern 221 is the same as the shape of the hollowed-out region 31. When the display subpanel 11 and the transparent substrate 10 are aligned and adhered, the relative position between the transparent substrate 10 and the display subpanel 11 is adjusted, so that the vertical projection of the second sub-pattern 221 on the transparent substrate 10 is located in the hollowed-out region 31, and then adhering and tiling are performed. In this manner, the vertical projection of the second sub-pattern 221 on the transparent substrate 10 is embedded in the hollowed-out region 31 of the first sub-pattern 211, thereby implementing high-precision tiling of the display subpanel 11 on the transparent substrate 10.

With continued reference to FIG. 2, in an embodiment, the area of the hollowed-out region 31 is equal to the area of the second sub-pattern 221. At this time, the pattern of the hollowed-out region 31 is completely the same as the pattern of the second sub-pattern 221. When the display subpanel 11 and the transparent substrate 10 are aligned and adhered, the relative position between the transparent substrate 10 and the display subpanel 11 is adjusted, so that the vertical projection of the second sub-pattern 221 on the transparent substrate 10 coincides with the hollowed-out region 31, and then adhering is performed, thereby implementing high-precision tiling of the display subpanel 11 on the transparent substrate 10.

At the same time, when the display subpanel 11 and the transparent substrate 10 are adhered and tiled, the alignment deviation of the display subpanel 11 on the transparent substrate 10 may also be directly acquired through the deviation between the vertical projection of the second sub-pattern 221 on the transparent substrate 10 and the hollowed-out region 31, so that the alignment situation of the current display subpanel 11 is determined. The relative position between the current display subpanel 11 and the transparent substrate 10 is correspondingly adjusted with reference to the preceding alignment deviation, thereby implementing high-precision tiling of the display subpanel 11 on the transparent substrate 10.

Similarly, after the display subpanel 11 and the transparent substrate 10 are adhered and tiled, the alignment deviation of an adhered display subpanel 11 on the transparent substrate 10 may also be directly acquired through the deviation between the vertical projection of the second sub-pattern 221 on the transparent substrate 10 and the hollowed-out region 31, so that the alignment situation of the adhered display subpanel 11 is determined. The alignments between a subsequent display subpanel 11 and the transparent substrate 10 is correspondingly adjusted with reference to the preceding alignment deviation, thereby implementing high-precision tiling between the subsequent display subpanel 11 and the adhered display subpanel 11.

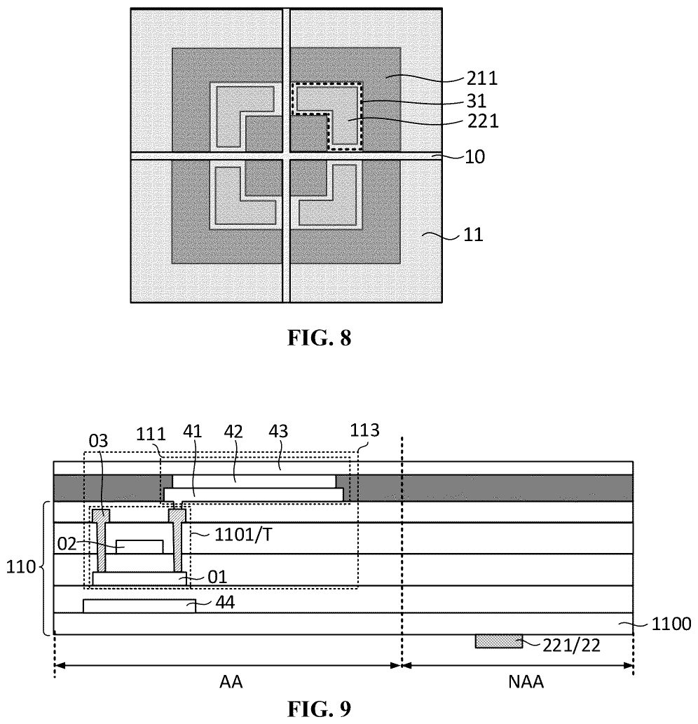

FIG. 8 is a partial view illustrating the structure of a tiled display panel according to an embodiment of the present disclosure. As shown in FIG. 8, in an embodiment, the area of the hollowed-out region 31 is greater than the area of the second sub-pattern 221. When the display subpanel 11 and the transparent substrate 10 are aligned and adhered, the relative position between the transparent substrate 10 and the display subpanel 11 is adjusted, so that the vertical projection of the second sub-pattern 221 on the transparent substrate 10 is located in the hollowed-out region 31, and then adhering is performed. At this time, the area of the hollowed-out region 31 is configured to be greater than the area of the second sub-pattern 221, so that certain offset space for the display subpanel 11 may be provided. When the offset distance of the display subpanel 11 is small (the vertical projection of the second sub-pattern 221 on the transparent substrate 10 does not exceed the range of the hollowed-out region 31), a subsequent tiling procedure is not affected. Thus, it is beneficial to improve the manufacturing yield of the tiled display panel.

It is to be noted that description is given with reference to FIGS. 1 to 7 by using an example in which only four first sub-patterns 211 are disposed in one tiled region 101, and four second sub-patterns 221 are correspondingly disposed on the display subpanel 11, which is not limited thereto. In other embodiments, the number of first sub-patterns 211 in one tiled region 101 and the number of second sub-patterns 221 on one display subpanel 11 may be set according to actual requirements. This is not limited in the embodiment of the present disclosure.

With continued reference to FIGS. 5 and 6, in an embodiment, the display subpanel 11 includes a display region AA and a non-display region NAA. The display region AA is configured to implement image display. In this embodiment, the second sub-pattern 221 on the display subpanel 11 may be disposed in the non-display region NAA. With this disposition, the distance between the second sub-pattern 221 and the geometric center of the display subpanel 11 may be made larger. If the display subpanel 11 is offset or twisted during tiling, relatively large misalignment may occur between the second sub-pattern 221 and the first sub-pattern 211. Thus, with the above disposition, it is convenient to measure the offset between the second sub-pattern 221 and the first sub-pattern 211 to determine the alignment deviation of the display subpanel 11 on the transparent substrate 10. The measurement accuracy is higher, and it is beneficial to improve the alignment accuracy.

For example, as shown in FIG. 5, the display subpanel 11 is provided with a second sub-pattern 221 in each of four diagonal positions to improve the alignment accuracy, which is not limited thereto.

The sizes of the first sub-pattern 211 and the second sub-pattern 221 may be 0.2 mm to 0.5 mm, so that no excessive space is occupied when a camera can clearly acquire a pattern image for alignment, which is not limited thereto.

In other embodiments, the second sub-pattern 221 on the display subpanel 11 may also be disposed in the display region AA. In this manner, it is beneficial to reduce the width of the non-display region NAA, so that it is beneficial to reduce the display gap between adjacent display subpanels 11, and the display effect of the tiled display panel is improved.

With continued reference to FIGS. 5 and 6, in an embodiment, the second alignment pattern 22 is disposed on the side of the base substrate 1100 adjacent to the pixel units 111. At this time, the second alignment pattern 22 can be prepared in the same manufacturing process as the film structure on the array substrate 110, thereby shortening the process time.

For example, description is given by using an example in which the display subpanel 11 is an OLED display panel. The driver circuits 1101 and the pixel units 111 are disposed in sequence on a side of the base substrate 1100. A driver circuit 1101 and a pixel unit 111 are electrically connected correspondingly to drive the pixel unit 111 to emit light to implement a display function.

The pixel unit 111 may include an anode layer 41, an emission layer 42, and a cathode layer 43 that are stacked. The emission layer 42 may be an organic emission layer (EML). Electrons are injected into the emission layer 42 through the cathode layer 43. Holes are injected into the emission layer 42 through the anode layer 41. The electrons and the holes are recombined in the emission layer 42 to emit light.

The driver circuit 1101 may include at least one thin-film transistor T. The thin-film transistor T may include an active layer 01, a gate layer 02, and a source and drain layer 03 that are stacked. Insulating layers are disposed between the active layer 01 and the gate layer 02 and between the gate layer 02 and the source and drain layer 03 to isolate the active layer 01, the gate layer 02, and the source and drain layer 03 to ensure the normal operation of the thin-film transistor T.

With continued reference to FIGS. 5 and 6, in an embodiment, the display subpanel 11 also includes a light-shielding metal layer 44. The light-shielding metal layer 44 is located on the side of the active layer 01 facing the base substrate 1100. In the thickness direction of the base substrate 1100, the light-shielding metal layer 44 at least partially overlaps the active layer 01. The light-shielding metal layer 44 is configured to shield the channel formed by the active layer 01 to prevent external ambient light from irradiating the active layer 01, thereby preventing the active layer 01 from being affected by light and affecting the off-state current of the thin-film transistor T.

In this embodiment, as shown in FIG. 6, the second alignment pattern 22 and the light-shielding metal layer 44 may be located in the same film, so that the number of films can be reduced, thereby reducing production costs and reducing the thickness of the display panel. At the same time, the second alignment pattern 22 and the light-shielding metal layer 44 may be made of the same metal material, so that the second alignment pattern 22 and the light-shielding metal layer 44 can be prepared in the same process, thereby shortening the process time.

The second alignment pattern 22 and the light-shielding metal layer 44 are configured to be located in the same film, so that the number of films between the second alignment pattern 22 and the base substrate 1100 can be reduced. Thus, in the process in which the display subpanel 11 is tiled on the transparent substrate 10, the camera can acquire the image of the second alignment pattern 22 on the display subpanel 11 more clearly through the transparent substrate 10 and the base substrate 1100.

In other embodiments, the second alignment pattern 22 may also be located in the same film as other structures. For example, the second alignment pattern 22 and the gate layer 02 are located in the same film to reduce production costs and shorten the process time. This is not limited in this embodiment of the present disclosure.

It is to be noted that the base substrate 1100, a conductor film, an insulating film, and a semiconductor film in the array substrate 110 may all be made of transparent materials. Thus, in the process in which the display subpanel 11 is tiled on the transparent substrate 10, the camera can acquire the image of the second alignment pattern 22 on the display subpanel 11 through films such as the transparent substrate 10 and the base substrate 1100.

At the same time, in the adhering process of the display subpanel 11 and the transparent substrate 10, the camera may also be disposed on a side of the display subpanel 11 to pick up the first alignment pattern 21 on the transparent substrate 10 and the second alignment pattern 22 on the display subpanel 11 through a transparent structure in the display subpanel 11. Then, the relative position between the transparent substrate 10 and the display subpanel 11 is adjusted, the second sub-pattern 221 of the second alignment pattern 22 is guided to be located in the hollowed-out region 31 of the first sub-pattern 211 in the first alignment pattern 21, and adhering is started, thereby implementing high-precision tiling of the display subpanel 11 on the transparent substrate 10.

FIG. 9 is a partial sectional view illustrating the structure of a tiled display panel according to an embodiment of the present disclosure. As shown in FIG. 9, in an embodiment, the second alignment pattern 22 is disposed on the side of the base substrate 1100 facing away from a pixel unit 111. Thus, in the process in which the display subpanel 11 is tiled on the transparent substrate 10, the camera only needs to acquire the image of the second alignment pattern 22 on the display subpanel 11 through the transparent substrate 10. Thus, it is beneficial to improve the clarity of the image.

In an embodiment, the materials of the first alignment pattern 21 and the second alignment pattern 22 may include a metal material or a black matrix (BM) material. The metal may include copper, and the BM material may include a resin, which is not limited thereto.

When the first alignment pattern 21 and the second alignment pattern 22 are made of metal materials, the thickness of the first alignment pattern 21 and the thickness of the second alignment pattern 22 may be 100 nm to 1 μm; and when the first alignment pattern 21 and the second alignment pattern 22 are made of BM materials, the thickness of the first alignment pattern 21 and the thickness of the second alignment pattern 22 may be 4 μm to 5 μm, which is not limited thereto.

The first alignment pattern 21 and the second alignment pattern 22 may be made by an exposure and development process, or the first alignment pattern 21 and the second alignment pattern 22 may be made by a laser engraving process. This is not limited in the embodiment of the present disclosure.

In summary, in the tiled display panel provided by this embodiment of the present disclosure, the transparent substrate and at least two display subpanels are included. The transparent substrate includes at least two tiled regions. The at least two display subpanels are disposed in the at least two tiled regions respectively. In this manner, the structural strength and flatness of the whole tiled display panel can be improved. At the same time, the transparent substrate also includes a first alignment pattern. The first alignment pattern includes at least two first sub-patterns. The at least two first sub-patterns are disposed in the at least two tiled regions respectively. The first sub-pattern includes a hollowed-out region. The tiled display panel includes a second alignment pattern. The second alignment pattern includes at least two second sub-patterns. The shape of the second sub-pattern is the same as the shape of the hollowed-out region. When the display subpanel is aligned and tiled on the transparent substrate, the vertical projection of the second sub-pattern on the transparent substrate is located in the hollowed-out region, so that high-precision alignment and tiling of the display subpanel on the transparent substrate are implemented. Compared with a manual tiling method, a better tiling effect can be obtained, and a tiling application scenario of small pixel spacing and high resolution is satisfied.

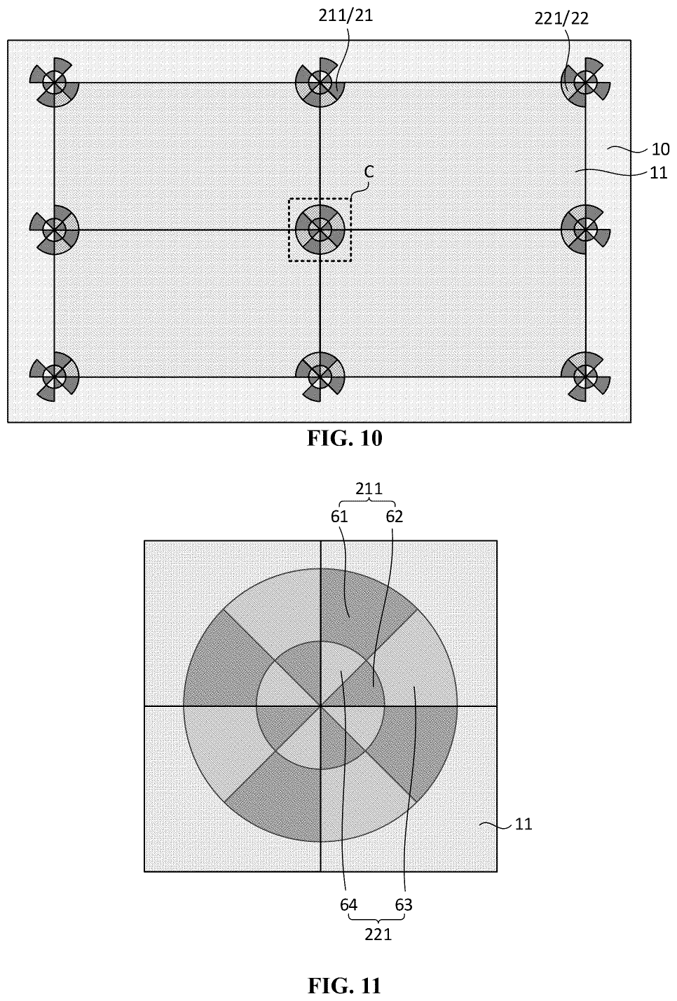

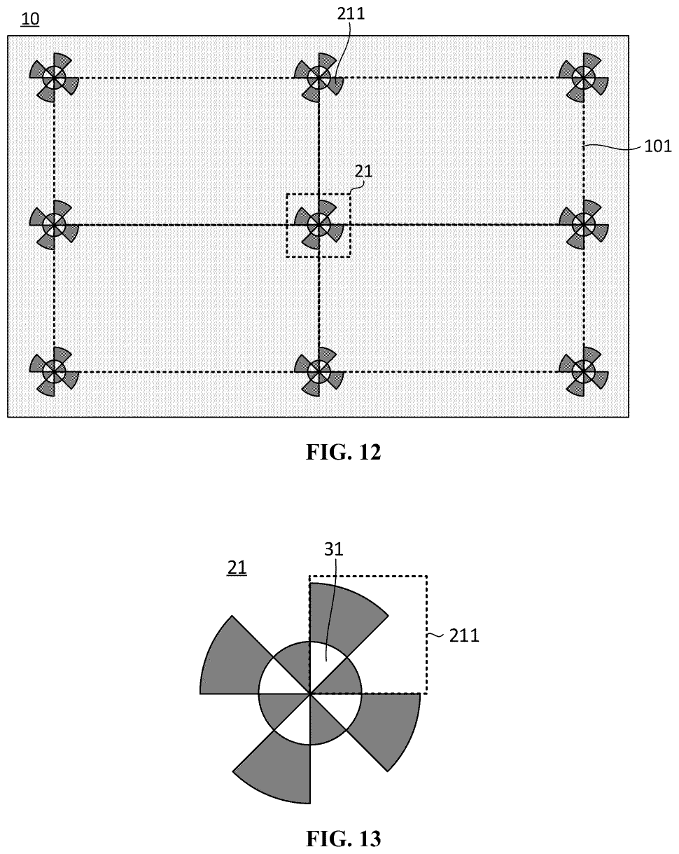

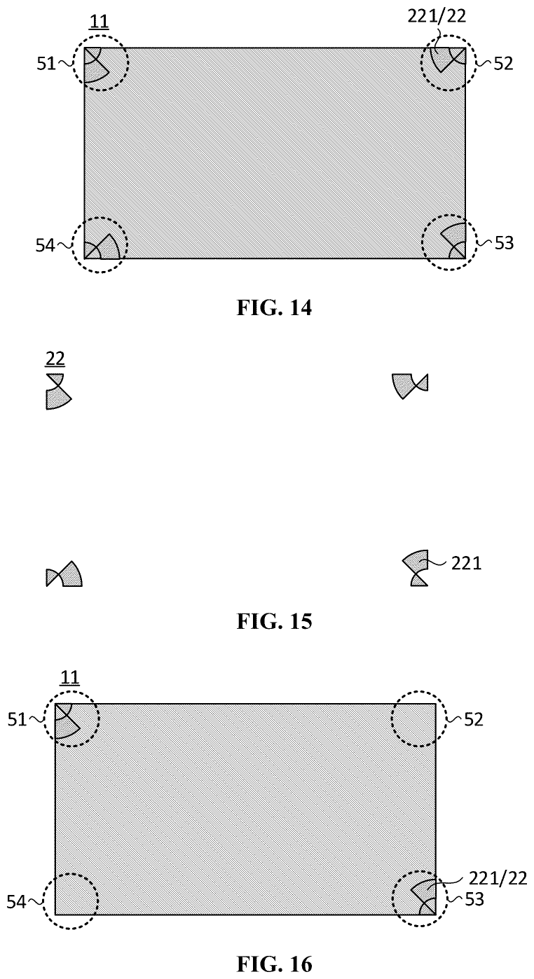

FIG. 10 is a diagram illustrating the structure of another tiled display panel according to an embodiment of the present disclosure. FIG. 11 is an enlarged view illustrating the structure of part C of FIG. 10. FIG. 12 is a diagram illustrating the structure of another transparent substrate according to an embodiment of the present disclosure. FIG. 13 is a diagram illustrating the structure of another first alignment pattern according to an embodiment of the present disclosure. FIG. 14 is a diagram illustrating the structure of another display subpanel according to an embodiment of the present disclosure. FIG. 15 is a diagram illustrating the structure of another second alignment pattern according to an embodiment of the present disclosure. As shown in FIGS. 10 to 15, in an embodiment, the transparent substrate includes at least two first alignment patterns 21. The at least two first alignment patterns 21 have the same shape.

As shown in FIGS. 10 to 15, multiple first alignment patterns 21 on the transparent substrate 10 are configured to have the same shape. When display subpanels 11 corresponding to different tiled regions 101 on the transparent substrate 10 are tiled, first alignment patterns 21 of the different tiled regions 101 picked up by the camera have the same shape. Thus, it is only necessary to match the shape of one first alignment pattern 21 to complete alignment and tiling of multiple display subpanels 11. It is beneficial to improve the recognition efficiency of the image, thereby improving the alignment efficiency of the display subpanels 11.

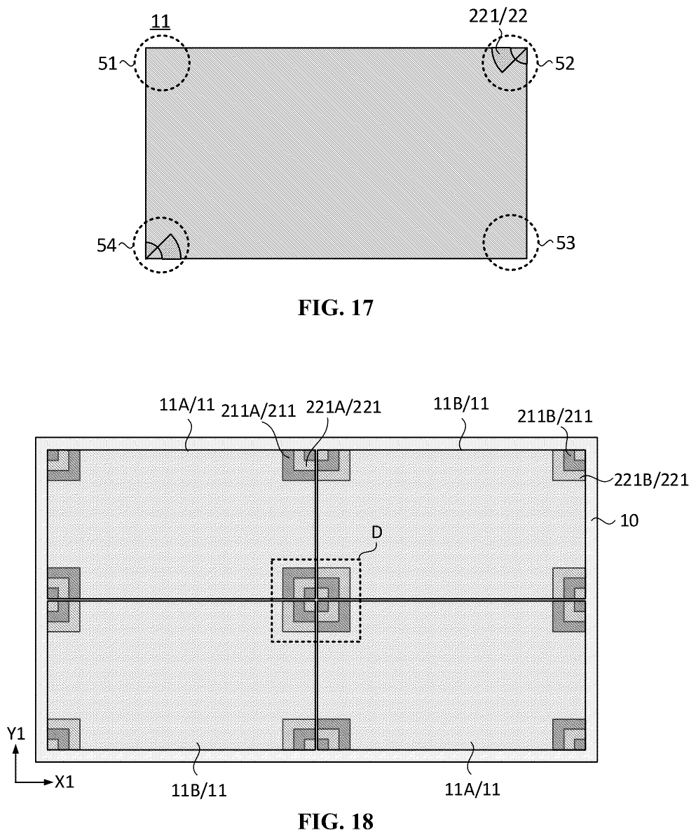

FIG. 16 is a diagram illustrating the structure of another display subpanel according to an embodiment of the present disclosure. FIG. 17 is a diagram illustrating the structure of another display subpanel according to an embodiment of the present disclosure. As shown in FIGS. 14, 16, and 17, in an embodiment, a display subpanel 11 includes a first vertex angle region 51, a second vertex angle region 52, a third vertex angle region 53, and a fourth vertex angle region 54. The first vertex angle region 51 and the third vertex angle region 53 are disposed opposite to each other. The second vertex angle region 52 and the fourth vertex angle region 54 are disposed opposite to each other. The first vertex angle region 51 and the third vertex angle region 53 are provided with second sub-patterns 221. A second sub-pattern 221 in the third vertex angle region 53 is rotated 180° relative to a second sub-pattern 221 in the first vertex angle region 51. Moreover/Alternatively, the second vertex angle region 52 and the fourth vertex angle region 54 are provided with the second sub-patterns 221. A second sub-pattern 221 in the fourth vertex angle region 54 is rotated 180° relative to a second sub-pattern 221 in the second vertex angle region 52.

In an embodiment, as shown in FIG. 16, on a display subpanel 11, the first vertex angle region 51, the second vertex angle region 52, the third vertex angle region 53, and the fourth vertex angle region 54 are arranged in a clockwise direction. Only the first vertex angle region 51 and the third vertex angle region 53 may be provided with the second sub-patterns 221. With this disposition, in one aspect, the distance between the second sub-patterns 221 and the geometric center of the display subpanel 11 are made larger. If the display subpanel 11 is offset or twisted during tiling, relatively large misalignment may occur between the second sub-pattern 221 and the first sub-pattern 211. Thus, it is convenient to measure the offset between the second sub-pattern 221 and the first sub-pattern 211 to determine the alignment deviation of the display subpanel 11 on the transparent substrate 10. On the other hand, the distance between the two second sub-patterns 221 is relatively long. If the display subpanel 11 is offset or twisted during tiling, the overall alignment deviation situation of the display subpanel 11 on the transparent substrate 10 can be more easily determined through the offset situation between different second sub-patterns 221 and the corresponding first sub-patterns 211. The measurement accuracy is higher, and it is beneficial to improve the alignment accuracy.

In an embodiment, the second sub-pattern 221 in the third vertex angle region 53 is rotated 180° relative to the second sub-pattern 221 in the first vertex angle region 51. That is, the second sub-pattern 221 in the third vertex angle region 53 is rotationally-symmetrical with respect to the second sub-pattern 221 in the first vertex angle region 51 by 180°. With this disposition, it is beneficial to make multiple first alignment patterns 21 corresponding to the second alignment pattern 22 on the transparent substrate 10 have the same shape. When display subpanels 11 corresponding to different tiled regions 101 on the transparent substrate 10 are tiled, the camera only needs to match the shape of one first alignment pattern 21 to complete alignment and tiling of multiple display subpanels 11. It is beneficial to improve the recognition efficiency of the image, thereby improving the alignment efficiency of the display subpanels 11.

Similarly, as shown in FIG. 17, only the second vertex angle region 52 and the fourth vertex angle region 54 may be provided with second sub-patterns 221 to improve the alignment accuracy. At the same time, the second sub-pattern 221 in the second vertex angle region 52 is rotated 180° relative to the second sub-pattern 221 in the fourth vertex angle region 54. That is, the second sub-pattern 221 in the second vertex angle region 52 is rotationally-symmetrical with respect to the second sub-pattern 221 in the fourth vertex angle region 54 by 180°. Thus, multiple first alignment patterns 21 corresponding to the second alignment pattern 22 on the transparent substrate 10 have the same shape. In this manner, the recognition efficiency of the image is improved, thereby improving the alignment efficiency of the display subpanels 11.

With continued reference to FIG. 14, second sub-patterns 221 may be disposed in the first vertex angle region 51, the second vertex angle region 52, the third vertex angle region 53, and the fourth vertex angle region 54 at the same time to further improve the alignment accuracy. At the same time, the second sub-pattern 221 in the third vertex angle region 53 is rotationally-symmetrical with respect to the second sub-pattern 221 in the first vertex angle region 51 by 180°. The second sub-pattern 221 in the second vertex angle region 52 is rotationally-symmetrical with respect to the second sub-pattern 221 in the fourth vertex angle region 54 by 180°. Thus, multiple first alignment patterns 21 corresponding to the second alignment pattern 22 on the transparent substrate 10 have the same shape. In this manner, the recognition efficiency of the image is improved, thereby improving the alignment efficiency of the display subpanels 11. This is not limited in the embodiment of the present disclosure.

With continued reference to FIGS. 10 to 15, in an embodiment, a display subpanel 11 includes a first vertex angle region 51, a second vertex angle region 52, a third vertex angle region 53, and a fourth vertex angle region 54 arranged in a clockwise direction. The second sub-patterns 221 are disposed in the first vertex angle region 51, the second vertex angle region 52, the third vertex angle region 53, and the fourth vertex angle region 54. A second sub-pattern 221 of the first vertex angle region 51, a second sub-pattern 221 of the second vertex angle region 52, a second sub-pattern 221 of the third vertex angle region 53, and a second sub-pattern 221 of the fourth vertex angle region 54 are rotated 90° clockwise in sequence.

In an embodiment, as shown in FIG. 14, on the display subpanel 11, the first vertex angle region 51, the second vertex angle region 52, the third vertex angle region 53, and the fourth vertex angle region 54 are arranged in a clockwise direction. The second sub-patterns 221 are disposed in the first vertex angle region 51, the second vertex angle region 52, the third vertex angle region 53, and the fourth vertex angle region 54. With this disposition, on the one hand, the distance between the second sub-pattern 221 and the geometric center of the display subpanel 11 may be made larger. If the display subpanel 11 is offset or twisted during tiling, relatively large misalignment may occur between the second sub-pattern 221 and the first sub-pattern 211. Thus, with the above disposition, it is convenient to measure the offset between the second sub-pattern 221 and the first sub-pattern 211 to determine the alignment deviation of the display subpanel 11 on the transparent substrate 10. On the other hand, the distances between four two second sub-patterns 221 are relatively long. If the display subpanel 11 is offset or twisted during tiling, the overall alignment deviation situation of the display subpanel 11 on the transparent substrate 10 can be more easily determined through the offset situation between the different second sub-patterns 221 and the corresponding first sub-patterns 211. The measurement accuracy is higher, and it is beneficial to improve the alignment accuracy.

In an embodiment, as shown in FIGS. 10 to 15, the second sub-pattern 221 in the second vertex angle region 52 is rotationally-symmetrical with respect to the second sub-pattern 221 in the first vertex angle region 51 by 90° in the clockwise direction. The second sub-pattern 221 in the third vertex angle region 53 is rotationally-symmetrical with respect to the second sub-pattern 221 in the second vertex angle region 52 by 90° in the clockwise direction. The second sub-pattern 221 in the fourth vertex angle region 54 is rotationally-symmetrical with respect to the second sub-pattern 221 in the third vertex angle region 53 by 90° in the clockwise direction. The second sub-pattern 221 in the first vertex angle region 51 is rotationally-symmetrical with respect to the second sub-pattern 221 in the fourth vertex angle region 54 by 90° in the clockwise direction. With this disposition, it is beneficial to make multiple first alignment patterns 21 corresponding to the second alignment pattern 22 on the transparent substrate 10 have the same shape. When display subpanels 11 corresponding to different tiled regions 101 on the transparent substrate 10 are tiled, the camera only needs to match the shape of one first alignment pattern 21 to complete alignment and tiling of multiple display subpanels 11. It is beneficial to improve the recognition efficiency of the image, thereby improving the alignment efficiency of the display subpanels 11.

With continued reference to FIGS. 1 to 15, in an embodiment, the area of a first sub-pattern 211 is greater than or equal to the area of a second sub-pattern 221.

In an embodiment, as shown in FIGS. 1 to 8, the area of a single first sub-pattern 211 may be configured to be greater than the area of a single second sub-pattern 221. With this disposition, the space occupied by the second sub-pattern 221 on the display subpanel 11 may be reduced. If the second sub-pattern 221 is located in the non-display region, it is beneficial to reduce the border width of the display subpanel 11, thereby reducing the display gap between adjacent display subpanels 11 and improving the tiled display effect. If the second sub-pattern 221 is located in the non-display region, it is beneficial to provide more wiring space for other display functional wires in the display region.

It is to be understood that the number of first sub-patterns 211 and the number of the second sub-patterns 221 are the same and correspondingly set. Thus, in this embodiment, the area of the first alignment pattern 21 combined by multiple first sub-patterns 211 is greater than the area of the second alignment pattern 22 combined by multiple second sub-patterns 221. Thus, the space occupied by the second alignment pattern 22 on the display subpanel 11 is reduced, and it is beneficial to reduce the border width of the display subpanel 11, thereby reducing the display gap between adjacent display subpanels 11 and improving the tiled display effect.

With continued reference to FIGS. 10 to 15, the area of a single first sub-pattern 211 may also be configured to be equal to the area of a single second sub-pattern 221 to reduce the area difference between the first sub-pattern 211 and the second sub-pattern 221. With this disposition, it can be avoided that the area of the first sub-pattern 211 or the area of the second sub-pattern 221 is too small, and the recognition efficiency of the first sub-pattern 211 or the recognition efficiency of the second sub-pattern 221 during alignment is affected, thereby improving the alignment efficiency of the display subpanels 11.

It is to be understood that the number of first sub-patterns 211 and the number of the second sub-patterns 221 are the same and correspondingly set. Thus, in this embodiment, the area of the first alignment pattern 21 combined by multiple first sub-patterns 211 is equal to the area of the second alignment pattern 22 combined by multiple second sub-patterns 221 to reduce the area difference between the first sub-pattern 211 and the second sub-pattern 221. Thus, the recognition efficiency of the first sub-pattern 211 or the recognition efficiency of the second sub-pattern 221 during alignment is improved, thereby improving the alignment efficiency of the display subpanels 11.

With continued reference to FIGS. 1 to 7, in an embodiment, the first sub-pattern 211 includes a first pattern subsection 61 and a second pattern subsection 62. In this manner, the vertical projection of the second sub-pattern 221 on the transparent substrate 10 is located between the first pattern subsection 61 and the second pattern subsection 62.

In an embodiment, as shown in FIG. 2, the vertical projection of the second sub-pattern 221 on the transparent substrate 10 is configured to be located between the first pattern subsection 61 and the second pattern subsection 62. If the display subpanel 11 is offset or twisted during tiling, the alignment deviation direction and deviation value of the display subpanel 11 on the transparent substrate 10 can be more easily determined through the gap size between the second sub-pattern 221 and the first pattern subsection 61 and the gap size between the second sub-pattern 221 and the second pattern subsection 62. Thus, it is beneficial to improve the alignment efficiency and the alignment accuracy.

With continued reference to FIGS. 10 to 15, in an embodiment, the first sub-pattern 211 includes a first pattern subsection 61 and a second pattern subsection 62. The second sub-pattern includes a third pattern subsection 63 and a fourth pattern subsection 64. In a clockwise direction, the first pattern subsection 61, the third pattern subsection 63, the second pattern subsection 62, and the fourth pattern subsection 64 are arranged in sequence.

In an embodiment, as shown in FIG. 11, the first pattern subsection 61, the third pattern subsection 63, the second pattern subsection 62, and the fourth pattern subsection 64 are arranged in sequence in the clockwise direction. In the clockwise direction, the third pattern subsection 63 or the fourth pattern subsection 64 is included between the first pattern subsection 61 and the second pattern subsection 62, that is, the vertical projection of the third pattern subsection 63 or the fourth pattern subsection 64 on the transparent substrate 10 is located in the hollowed-out region between the first pattern subsection 61 and the second pattern subsection 62. With this disposition, if the display subpanel 11 is offset or twisted in any direction during tiling, more rapid determination can be implemented through the offset between the first pattern subsection 61, the third pattern subsection 63, the second pattern subsection 62, and the fourth pattern subsection 64. Thus, the alignment efficiency and the alignment accuracy are improved.

With continued reference to FIGS. 1 to 7, in an embodiment, the contour line of the second sub-pattern 221 includes a first straight line 71 and a second straight line 72. The extension direction of the first straight line 71 is perpendicular to the extension direction of the second straight line 72.

In an embodiment, as shown in FIG. 2, the contour line of the second sub-pattern 221 refers to the outer edge boundary of the second sub-pattern 221. The contour line of the second sub-pattern 221 includes two straight line segments perpendicular to each other, namely the first straight line 71 and the second straight line 72. Thus, the contour line of the first sub-pattern 211 corresponding to the second sub-pattern 221 also includes two straight line segments that are perpendicular to each other.

When the display subpanel 11 is tiled on the transparent substrate 10, the display subpanel is offset in the extension direction of the first straight line 71 or in the extension direction of the second straight line 72, which can be determined by the offset between the first straight line 71 or the second straight line 72 and the first sub-pattern 211. Thus, the alignment efficiency and the alignment accuracy are improved.

With continued reference to FIGS. 1 to 7, in an embodiment, the display subpanel 11 includes a first side 81 and a second side 82. The extension direction of the first side 81 is perpendicular to the extension direction of the second side 82. The first straight line 71 is parallel to the first side 81, and the second straight line 72 is parallel to the second side 82.

In an embodiment, as shown in FIG. 5, description is given by using an example in which the shape of the subpanel 11 is rectangular. The display subpanel 11 includes the first side 81 and the second side 82 perpendicular to each other. The first straight line 71 on the contour line of the second sub-pattern 221 is configured to be parallel to the first side 81, and the second straight line 72 on the contour line of the second sub-pattern 221 is configured to be parallel to the second side 82. That is, the extension direction of the first straight line 71 is the same as the extension direction of the first side 81, and the extension direction of the second straight line 72 is the same as the extension direction of the second side 82. When the display subpanel 11 and the transparent substrate 10 are aligned and tiled, the tiling deviation situation of the display subpanel 11 on the transparent substrate 10 can be more easily determined through the offset situation between the first straight line 71 or the second straight line 72 and the first sub-pattern 211. Thus, it is convenient to adjust the positions of subsequent adjacent display subpanels 11 according to the offset regular pattern of the adhered display subpanels 11, so that the alignment efficiency and the tiling effect are improved.

FIG. 18 is a diagram illustrating the structure of another tiled display panel according to

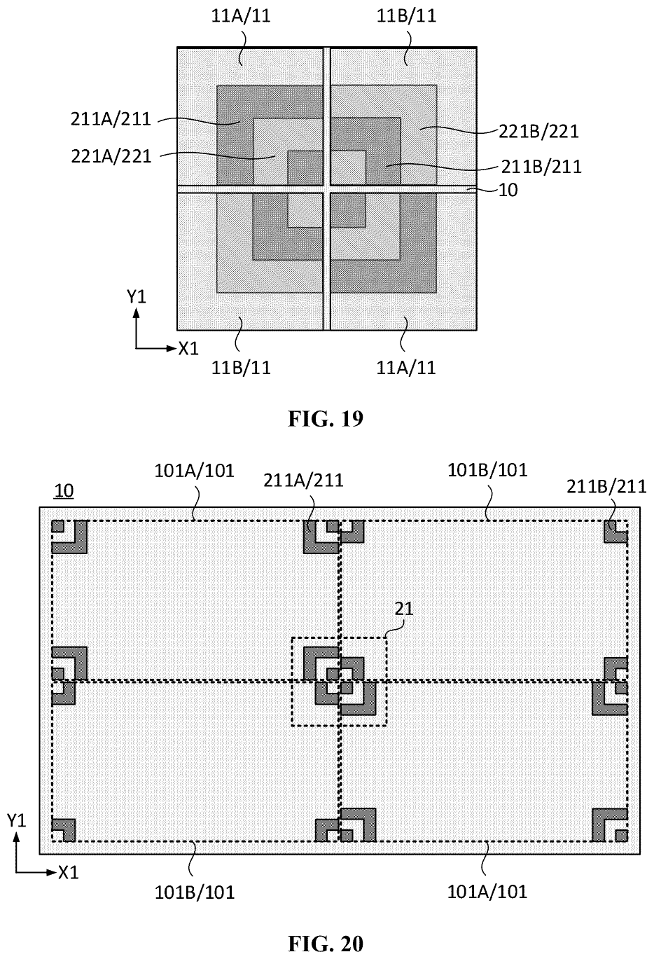

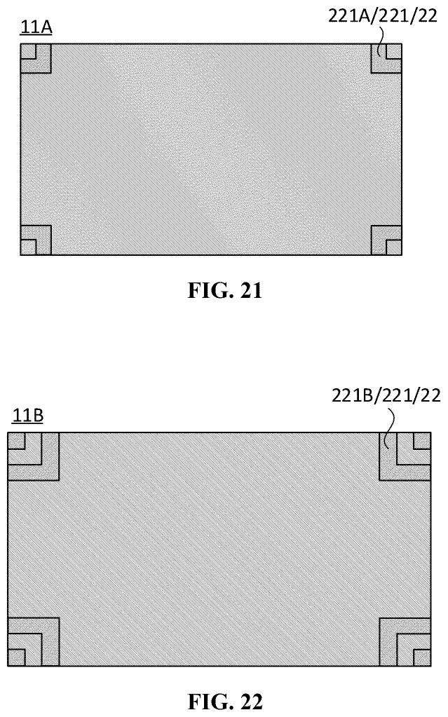

an embodiment of the present disclosure. FIG. 19 is an enlarged view illustrating the structure of part D of FIG. 18. FIG. 20 is a diagram illustrating the structure of another transparent substrate according to an embodiment of the present disclosure. FIG. 21 is a diagram illustrating the structure of a first display subpanel according to an embodiment of the present disclosure. FIG. 22 is a diagram illustrating the structure of a second display subpanel according to an embodiment of the present disclosure. As shown in FIGS. 18 to 22, in an embodiment, at least two tiled regions 101 include a first tiled region 101A and a second tiled region 101B. At least two display subpanels 11 include a first display subpanel 11A and a second display subpanel 11B. The first display subpanel 11A is correspondingly disposed in the first tiled region 101A. The second display subpanel 11B is correspondingly disposed in the second tiled region 101B. A first sub-pattern 211 in the first tiled region 101A is a first pattern 211A. A first sub-pattern 211 in the second tiled region 101B is a second pattern 211B. A second sub-pattern 221 on the first display subpanel 11A is a third pattern 221A. A second sub-pattern 221 on the second display subpanel 11B is a fourth pattern 221B. The first pattern 211A and the fourth pattern 221B have the same shape. The second pattern 211B and the third pattern 221A have the same shape.

In an embodiment, as shown in FIGS. 18 to 22, the first sub-pattern 211 (the first pattern 211A) in the first tiled region 101A and the second sub-pattern 221 (the fourth pattern 221B) on the second display subpanel 11B are configured to have the same shape. The first sub-pattern 211 (the second pattern 211B) in the second tiled region 101B and the second sub-pattern 221 (the third pattern 221A) on the first display subpanel 11A have the same shape. It is to be understood that the shape of the first sub-pattern 211 (the first pattern 211A) in the first tiled region 101A and the shape of the second sub-pattern 221 (the third pattern 221A) in the first display subpanel 11A are exchanged to obtain the first sub-pattern 211 (the second pattern 211B) in the second tiled region 101B and the second sub-pattern 221 (the fourth pattern 221B) in the second display subpanel 11B. Compared with the solution shown in FIG. 1, when the first display subpanel 11A and the second display subpanel 11B are adhered and tiled on the transparent substrate 10, in the case where the position of the camera is unchanged, it can be equivalent to the fact that the combined images of the first sub-pattern 211 and the second sub-pattern 221 are acquired from different directions for alignment. Thus, it is beneficial to improve the recognition efficiency and the alignment accuracy.

At the same time, when the first display subpanel 11A and the second display subpanel 11B are adhered and tiled on the transparent substrate 10, the combined images of the first sub-pattern 211 and the second sub-pattern 221 that are acquired by the camera have the same shape. It is beneficial to improve the recognition efficiency of the image, thereby improving the alignment efficiency of the display subpanels 11.

With continued reference to FIGS. 18 to 22, in this embodiment, the area of a single first sub-pattern 211 may be configured to be unequal to the area of the corresponding single second sub-pattern 221. In this manner, the image difference between the first sub-pattern 211 and the second sub-pattern 221 may be increased. After the shape of the first sub-pattern 211 (the first pattern 211A) in the first tiled region 101A and the shape of the second sub-pattern 221 (the third pattern 221A) in the first display subpanel 11A are exchanged to obtain the first sub-pattern 211 (the second pattern 211B) in the second tiled region 101B and the second sub-pattern 221 (the fourth pattern 221B) in the second display subpanel 11B, it is beneficial to improve the recognition efficiency of the image, thereby improving the alignment efficiency of the display subpanels 11.

With continued reference to FIGS. 18 to 22, in an embodiment, the first display subpanel 11A and the second display subpanel 11B are arranged in a first direction X1. The first display subpanel 11A and the second display subpanel 11B are arranged in a second direction Y1. The first direction X1 intersects with the second direction Y1.

When each display subpanel 11 is tiled on the transparent substrate 10, the tiling method to align and tile the first display subpanel 11 starting from a certain position on the transparent substrate 10. Subsequently, each display subpanel 11 is tiled in sequence based on the first display subpanel 11. In the process in which each display subpanel 11 is aligned and tiled on the transparent substrate 10 in sequence, the offset of the adhered display subpanel 11 may gradually accumulate during the alignment and tiling process of the subsequent display subpanels 11. The same alignment pattern may cause a similar alignment deviation. The gradual accumulation of the similar alignment deviation may cause a significant alignment deviation in the display subpanel 11 that is adhered at the rear.

In this embodiment, as shown in FIGS. 18 to 22, the first display subpanel 11A and the second display subpanel 11B are configured to be alternately disposed in the first direction X1 and the second direction Y1 respectively. It is beneficial to cancel the offset of adjacent display subpanels 11 during tiling, thereby reducing the offset accumulation of each display subpanel 11 during tiling and improving the tiling effect.

It is to be noted that description is given with reference to FIG. 18 to FIG. 20 by using an example in which the first direction X1 is perpendicular to the second direction Y1, which is not limited thereto.

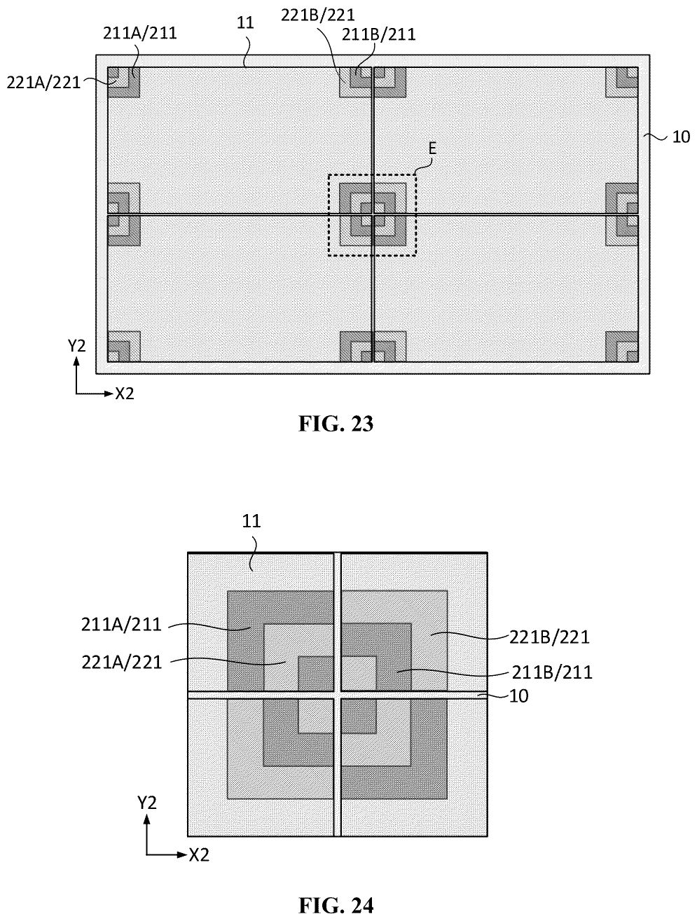

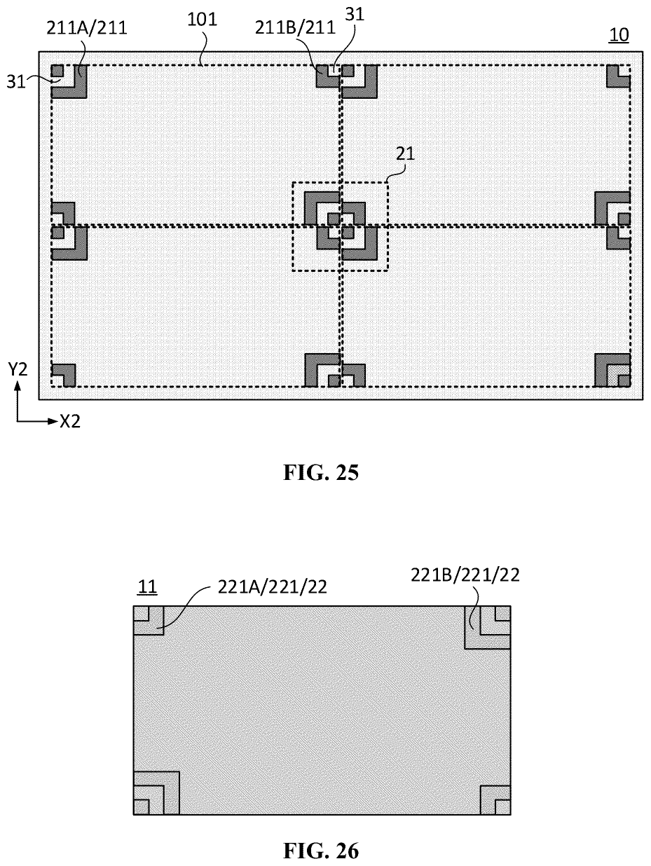

FIG. 23 is a diagram illustrating the structure of another tiled display panel according to an embodiment of the present disclosure. FIG. 24 is an enlarged view illustrating the structure of part E of FIG. 23. FIG. 25 is a diagram illustrating the structure of another transparent substrate according to an embodiment of the present disclosure. FIG. 26 is a diagram illustrating the structure of another display subpanel according to an embodiment of the present disclosure. As shown in FIGS. 23 to 26, in an embodiment, in a tiled region 101, at least two first sub-patterns 211 include a first pattern 211A and a second pattern 211B. In the display subpanel 11, at least two second sub-patterns 221 include a third pattern 221A and a fourth pattern 221B. The vertical projection of the third pattern 221A on the transparent substrate 10 is located in the hollowed-out region 31 of the first pattern 211A. The vertical projection of the fourth pattern 221B on the transparent substrate 10 is located in the hollowed-out region 31 of the second pattern 211B. The first pattern 211A and the fourth pattern 221B have the same shape. The second pattern 211B and the third pattern 221A have the same shape.

In an embodiment, as shown in FIGS. 23 to 26, first sub-patterns 211 (the first pattern 211A and the second pattern 211B) having different shapes are disposed in the same tiled region 101. Second sub-patterns 221 (the third pattern 221A and the fourth pattern 221B) with different shapes are correspondingly disposed in the same display subpanel 11. When the display subpanels 11 and the transparent substrate 10 are aligned and adhered, the relative positions between the transparent substrate 10 and the display subpanels 11 are adjusted. Thus, the vertical projection of the third pattern 221A on the transparent substrate 10 is located in the hollowed-out region 31 of the first pattern 211A, and the vertical projection of the fourth pattern 221B on the transparent substrate 10 is located in the hollowed-out region 31 of the second pattern 211B. The first pattern 211A and the fourth pattern 221B have the same shape, and the second pattern 211B and the third pattern 221A have the same shape, which may be understood that the shape of the first pattern 211A in the tiled region 101 and the shape of the third pattern 221A on the corresponding display subpanel 11 are exchanged to obtain the second pattern 211B in the same tiled region 101 and the fourth pattern 221B on the corresponding display subpanel 11. Compared with the solution shown in FIG. 1, when the display subpanels 11 and the transparent substrate 10 are adhered and tiled, in the case where the position of the camera is unchanged, it can be equivalent to the fact that the combined images of the first sub-pattern 211 and the second sub-pattern 221 are acquired from different directions for alignment. Thus, it is beneficial to improve the recognition efficiency and the alignment accuracy.

At the same time, when the display subpanel 11 and the transparent substrate 10 are adhered and tiled, the combined images of different first sub-patterns 211 and second sub-patterns 221 that are acquired by the camera have the same shape. It is beneficial to improve the recognition efficiency of the image, thereby improving the alignment efficiency of the display subpanels 11.

With continued reference to FIGS. 23 to 26, in an embodiment, in the display subpanel 11, the third pattern 221A and the fourth pattern 221B are arranged in a third direction X2. The third pattern 221A and the fourth pattern 221B are arranged in a fourth direction Y2. The third direction X2 intersects with the fourth direction Y2.

As shown in FIGS. 18 to 22, in the same display subpanel 11, the third pattern 221A and the fourth pattern 221B are configured to be arranged in the third direction X2 and the fourth direction Y2 respectively. Thus, it is beneficial to improve the alignment accuracy, and the tiling effect is improved.

It is to be noted that description is given with reference to FIG. 23 to FIG. 25 by using an example in which the third direction X2 is perpendicular to the fourth direction Y2, which is not limited thereto.

With continued reference to FIGS. 18 to 26, in an embodiment, the area of the first pattern 211A is different from the area of the third pattern 221A. The area of the second pattern 211B is different from the area of the fourth pattern 221B.

As shown in FIGS. 18 to 26, the area of a single first sub-pattern 211 (such as a first pattern 211A or a second pattern 211B) is further configured to be not equal to the area of a single second sub-pattern 221 (such as a third pattern 221A or a fourth pattern 221B) corresponding to the single first sub-pattern 211 to increase the image difference between the first sub-pattern 211 and the second sub-pattern 221. After the shape of the first pattern 211A in the tiled region 101 and the shape of the third pattern 221A on the corresponding display subpanel 11 are exchanged to obtain the second pattern 211B in the same tiled region 101 and the fourth pattern 221B on the corresponding display subpanel 11, or after the shape of the second pattern 211B in the tiled region 101 and the shape of the fourth pattern 221B on the corresponding display subpanel 11 are exchanged to obtain the first pattern 211A in the same tiled region 101 and the third pattern 221A on the corresponding display subpanel 11, the recognition efficiency of the image is further improved, thereby improving the alignment efficiency of the display subpanels 11.

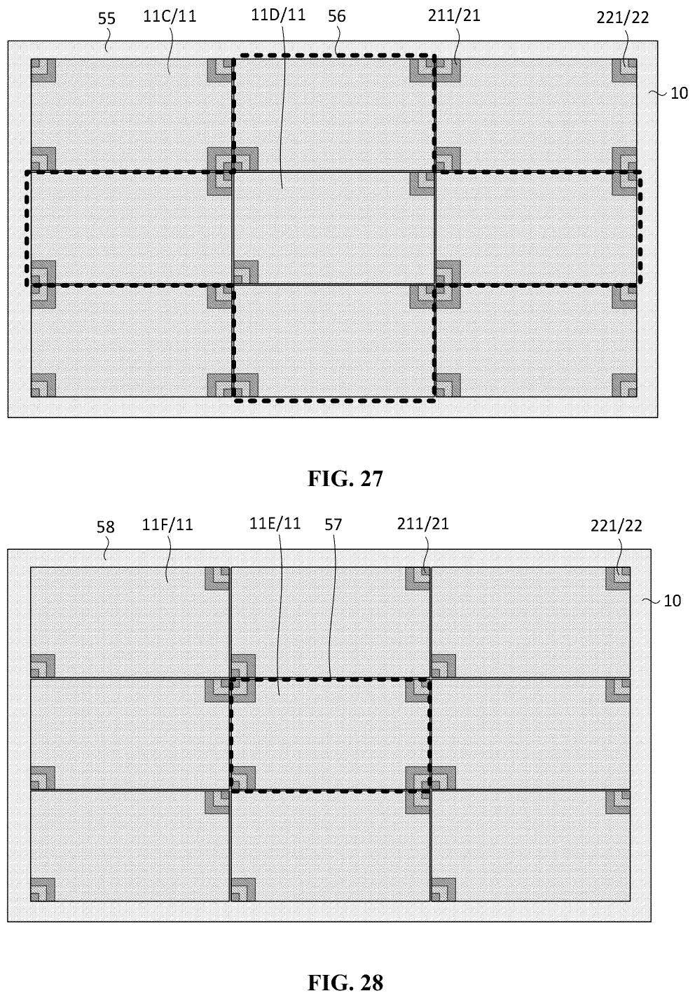

FIG. 27 is a diagram illustrating the structure of another tiled display panel according to an embodiment of the present disclosure. As shown in FIG. 27, in an embodiment, the tiled display panel of the embodiment of the present disclosure includes a vertex angle region 55 and a middle region 56. At least two display subpanels 11 include a third display subpanel 11C and a fourth display subpanel 11D. The vertical projection of the third display subpanel 11C on the tiled display panel is located in the vertex angle region 55. The vertical projection of the fourth display subpanel 11D on the tiled display panel is located in the middle region 56. The number of second sub-patterns 221 on the third display subpanel 11C is greater than the number of second sub-patterns 221 on the fourth display subpanel 11D.

In an embodiment, as shown in FIG. 27, the vertex angle region 55 is located at the vertex angle position of the tiled display panel. The region between vertex angle regions 55 is the middle region 56. The third display subpanel 11C is tiled in the vertex angle region 55. The fourth display subpanel 11D is tiled in the middle region 56.

In an embodiment, when each display subpanel 11 is tiled on the transparent substrate 10, the tiling method may be to align and tile the first display subpanel 11 (for example, the third display subpanel 11C) starting from the edge of a side of the transparent substrate 10 (for example, the vertex angle region 55). Subsequently, each display subpanel 11 (for example, the fourth display subpanel 11D) is tiled in sequence based on the position of the first display subpanel 11. Thus, the tiling direction of subsequent each display subpanel 11 is basically the same. The offset patterns of display subpanels 11 are similar. In this manner, it is convenient to adjust the positions of subsequent adjacent display subpanels 11 according to the offset pattern of the adhered display subpanel 11, so that the alignment efficiency and the tiling effect are improved.

Since the tiling offset is accumulated from a tiling origin, that is, the first display subpanel 11 (for example, the third display subpanel 11C tiled on the vertex angle region 55). Thus, the tiling of the first display subpanel 11 requires higher accuracy. In this embodiment, the number of second sub-patterns 221 on the third display subpanel 11C is configured to be greater than the number of second sub-patterns 221 on the fourth display subpanel 11D. When the third display subpanel 11C is tiled first, the tiling accuracy of the third display subpanel 11C can be improved, thereby reducing the impact on the tiling accuracy of a subsequent display subpanel 11 (for example, the fourth display subpanel 11D) and improving the tiling effect.

FIG. 28 is a diagram illustrating the structure of another tiled display panel according to

an embodiment of the present disclosure. As shown in FIG. 28, in an embodiment, the tiled display panel of the embodiment of the present disclosure includes a central region 57 and a periphery region 58 surrounding the central region 57. At least two display subpanels 11 include a fifth display subpanel 11E and a sixth display subpanel 11F. The vertical projection of the fifth display subpanel 11E on the transparent substrate 10 is located in the central region 57. The vertical projection of the sixth display subpanel 11F on the transparent substrate 10 is located in the periphery region 58. The number of second sub-patterns 221 on the fifth display subpanel 11E is greater than the number of second sub-patterns 221 on the sixth display subpanel 11F.

In an embodiment, as shown in FIG. 28, the central region 57 is located at the geometric center position of the tiled display panel. The periphery regions 58 are disposed around the central region 57. The fifth display subpanel 11E is tiled in the central region 57. The sixth display subpanels 11F are tiled in the periphery region 58.

In an embodiment, when each display subpanel 11 is tiled on the transparent substrate 10, the tiling method may be to align and tile the first display subpanel 11 (for example, the fifth display subpanel 11E) starting from the central region 57 of the transparent substrate 10. Subsequently, each display subpanel 11 (for example, the sixth display subpanel 11F) is tiled in sequence based on the position of the first display subpanel 11. Thus, the distance between the subsequent tiled display subpanel 11 and the tiled origin, that is, the first display subpanel 11 (for example, the fifth display subpanel 11E), is not too far, so that the offset accumulation of the subsequent display subpanel 11 during tiling can be reduced.

Since the tiling offset is accumulated from the tiling origin, that is, the first display subpanel 11 (for example, the fifth display subpanel 11E tiled on the central region 57). Thus, the tiling of the first display subpanel 11 requires higher accuracy. In this embodiment, the number of second sub-patterns 221 on the fifth display subpanel 11E is configured to be greater than the number of second sub-patterns 221 on the sixth display subpanel 11F. When the fifth display subpanel 11E is tiled first, the tiling accuracy of the fifth display subpanel 11E can be improved, thereby reducing the impact on the tiling accuracy of a subsequent display subpanel 11 (for example, the sixth display subpanel 11F) and improving the tiling effect.

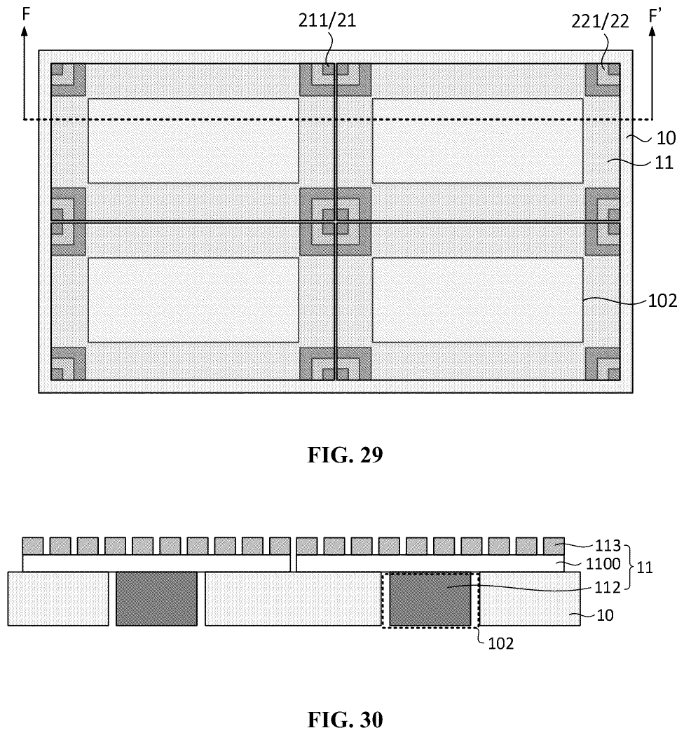

FIG. 29 is a diagram illustrating the structure of another tiled display panel according to an embodiment of the present disclosure. FIG. 30 is a sectional view taken along direction F-F′in FIG. 29. As shown in FIGS. 29 and 30, in an embodiment, the one display subpanel 11 includes a base substrate 1100, a driver structure 112, and multiple sub-pixels 113. The driver structure 112 is located on the side of the base substrate 1100 facing away from the sub-pixels 113. The transparent substrate 10 includes at least two openings 102. At least two openings 102 are disposed in the at least two tiled regions 101 respectively. The vertical projection of the driver structure 112 on the transparent substrate 10 is located in an opening 102.

In an embodiment, as shown in FIGS. 29 and 30, multiple sub-pixels 113 are disposed on a side of the base substrate 1100. A sub-pixel 113 is configured to emit light to implement a display function.

The sub-pixel 113 may include an organic light-emitting diode (OLED), a light-emitting diode (LED), a sub-millimeter light-emitting diode (mini LED), or a micron light-emitting diode (micro LED). This is not limited in the present disclosure.

For example, as shown in FIGS. 6 and 9, when the sub-pixel 113 is an organic light-emitting diode, the sub-pixel 113 may include a pixel unit 111 and a driver circuit 1101, which is not limited thereto.

In an embodiment, as shown in FIGS. 29 and 30, the driver structure 112 is disposed on the side of the base substrate 1100 facing away from the sub-pixels 113.

The driver structure 112 may include a flexible printed circuit (FPC) and/or a chip on film (COF). A driver chip may be disposed on the driver structure 112. The driver chip is configured to drive the display subpanel 11 to perform image display, which is not limited thereto.

As shown in FIGS. 29 and 30, in this embodiment, the openings 102 corresponding to the driver structures 112, respectively, are disposed on the transparent substrate 10. When the display subpanels 11 are tiled on the transparent substrate 10, the openings 102 may be configured for placing the driver structures 112 of the display subpanels 11, so that the display surfaces of the display subpanels 11 are basically on the same plane. In this manner, the flatness of the whole tiled display panel can be improved, and the tiled display effect is improved.

The size of the opening 102 may be set according to the size of the driver structure 112. For example, the size of the opening 102 is set to be 1 mm to 2 mm greater than the size of the driver structure 112. While the support strength of the transparent substrate 10 is ensured, the size of the opening 102 may be more than 2 mm greater than the size of the driver structure 112, so that the driver structure 112 passes through the opening 102 more easily when the display subpanel 11 is tiled on the transparent substrate 10, thereby improving the tiling efficiency.

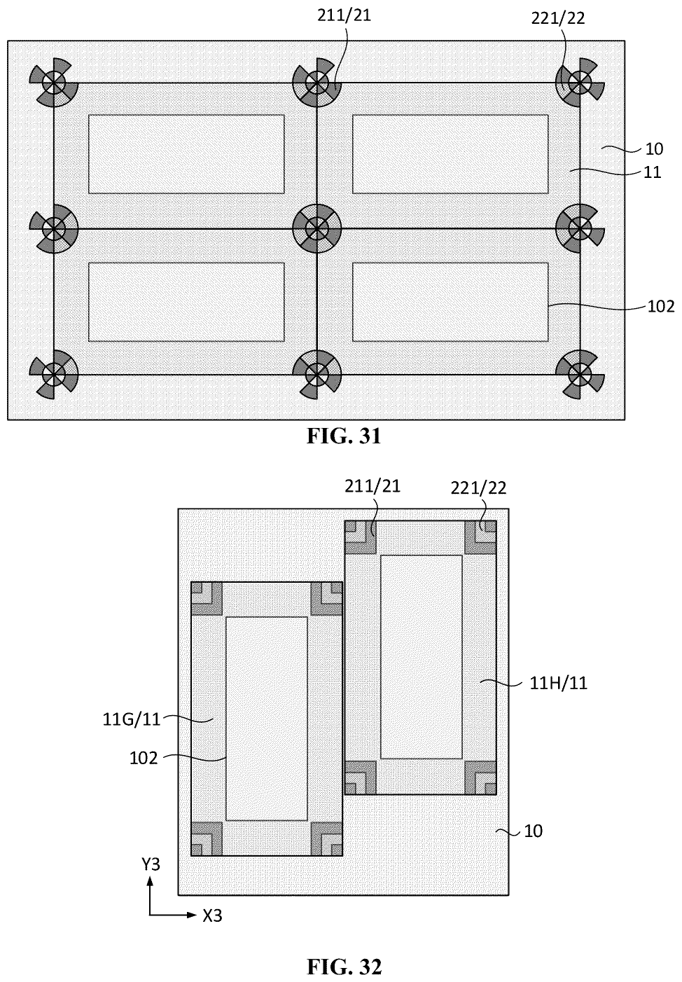

FIG. 31 is a diagram illustrating the structure of another tiled display panel according to an embodiment of the present disclosure. As shown in FIG. 31, in the tiled display panel provided by any preceding embodiment, an opening 102 corresponding to the driver structure 112 may be disposed on the transparent substrate 10 for placing the driver structure 112 of the display subpanel 11, so that the display surface of each display subpanel 11 is basically on the same plane. In this manner, the flatness of the whole tiled display panel is improved, the tiled display effect is improved, and the details are not repeated here.

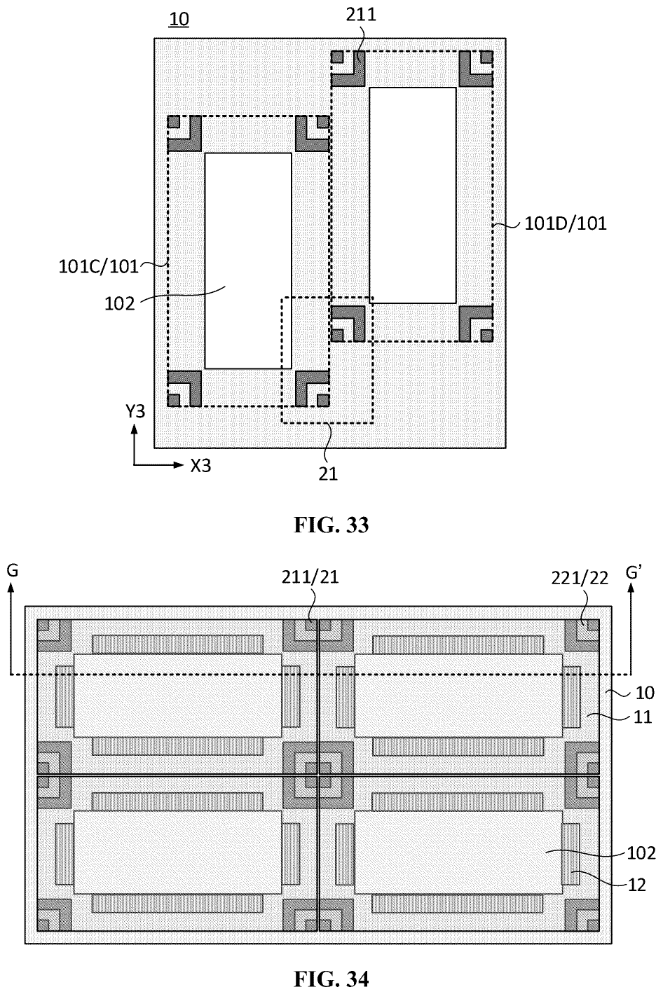

FIG. 32 is a diagram illustrating the structure of another tiled display panel according to an embodiment of the present disclosure. FIG. 33 is a diagram illustrating the structure of another transparent substrate according to an embodiment of the present disclosure. As shown in FIGS. 32 and 33, in an embodiment, at least two display subpanels 11 include a seventh display subpanel 11G and an eighth display subpanel 11H. The seventh display subpanel 11G and the eighth display subpanel 11H are disposed adjacent to each other. The arrangement direction of the seventh display subpanel 11G and the eighth display subpanel 11H is a fifth direction X3. The seventh display subpanel 11G and the eighth display subpanel 11H are arranged in a staggered manner in a sixth direction Y3. The sixth direction Y3 intersects with the fifth direction X3.

In an embodiment, as shown in FIGS. 32 and 33, the tiled display panel includes the seventh display subpanel 11G and the eighth display subpanel 11H. At least two tiled regions 101 on the transparent substrate 10 include the third tiled region 101C and the fourth tiled region 101D. The arrangement direction of the third tiled region 101C and the fourth tiled region 101D is the fifth direction X3. The third tiled region 101C and the fourth tiled region 101D are arranged in a staggered manner in the sixth direction Y3. When the seventh display subpanel 11G and the eighth display subpanel 11H are adhered and tiled on the transparent substrate 10, the second sub-pattern 221 on the seventh display subpanel 11G is matched with the first sub-pattern 211 in the third tiled region 101C, so that the seventh display subpanel 11G is tiled in the third tiled region 101C. The second sub-pattern 221 on the eighth display subpanel 11H is matched with the first sub-pattern 211 in the fourth tiled region 101D, so that the eighth display subpanel 11H is tiled in the fourth tiled region 101D. Finally, the arrangement direction of the seventh display subpanel 11G and the eighth display subpanel 11H is the fifth direction X3. The seventh display subpanel 11G and the eighth display subpanel 11H are arranged in a staggered manner in the sixth direction Y3. Thus, irregular tiling is implemented.

Since the existing process is convenient for processing the transparent substrate 10, and production accuracy of the first alignment pattern 21 on the transparent substrate 10 is high, in the embodiment of the present disclosure, the position of the first sub-pattern 211 on the transparent substrate 10 may be specially disposed to implement various forms of irregular tiling.

It is to be noted that the arrangement of the display subpanels 11 in the tiled display panel is not limited to Z-shaped tiling shown in FIG. 32 and FIG. 33. In other embodiments, the position of the tiled region 101 on the transparent substrate 10, the position of the first sub-pattern 211 in the tiled region 101, and the position of the opening 102 may be disposed according to the usage scenario of an irregular tiling product and the requirement of the irregular tiling position of the display subpanels 11. This is not limited in the embodiment of the present disclosure.

In addition, the number of display subpanels 11 in the tiled display panel is not limited to 2 (for example, as shown in FIG. 32), 4 (for example, as shown in FIG. 1 and FIG. 10), or 9 (for example, as shown in FIG. 27 and FIG. 28). In other embodiments, the number of display subpanels 11 in the tiled display panel may be set according to actual requirements. This is not limited in the embodiment of the present disclosure.

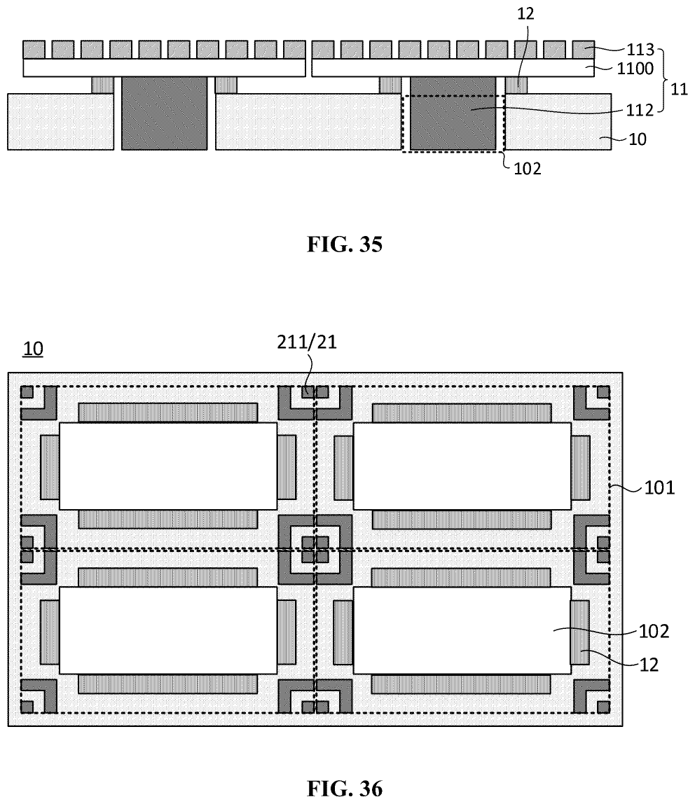

FIG. 34 is a diagram illustrating the structure of another tiled display panel according to an embodiment of the present disclosure. FIG. 35 is a sectional view taken along direction G-G′in FIG. 34. FIG. 36 is a diagram illustrating the structure of another transparent substrate according to an embodiment of the present disclosure. As shown in FIGS. 34 to 36, in an embodiment, an adhesive 12 is further disposed on the transparent substrate 10. The adhesive 12 is located between the transparent substrate 10 and the display subpanel 11. The adhesive 12 includes an ultraviolet viscose reduction adhesive.

In an embodiment, as shown in FIGS. 34 to 36, the transparent substrate 10 and the display subpanel 11 are adhered by using the adhesive 12, so that the display subpanel 11 can be reliably adhered to the transparent substrate 10, thereby preventing the display subpanel 11 from being misaligned and affecting the tiling effect.

With continued reference to FIGS. 34 to 36, in an embodiment, the adhesive 12 may be disposed around the opening 102, so that the display subpanel 11 may be evenly stressed during adhering. Thus, it is beneficial to improve the reliability of the adhesion and fixation between the transparent substrate 10 and the display subpanel 11.

The width of the adhesive 12 may be greater than or equal to 1 mm to ensure the reliability of the adhesion and fixation between the transparent substrate 10 and the display subpanel 11, which is not limited thereto.

In an embodiment, the adhesive 12 may use the ultraviolet viscose reduction adhesive. The viscosity of the ultraviolet viscose reduction adhesive may be reduced by ultraviolet light irradiation, so that the transparent substrate 10 can be removed from the tiled display panel. Thus, the detachable connection between the transparent substrate 10 and the display subpanel 11 is implemented, so that the thickness and weight of the tiled display panel are reduced, and a thin and light design is implemented. At the same time, the transparent substrate 10 may be reused to reduce manufacturing costs.

It is to be noted that in some embodiments, the transparent substrate 10 may also be retained in a final tiled display panel product to improve the reliability of the tiled display panel. This is not limited in the embodiment of the present disclosure.

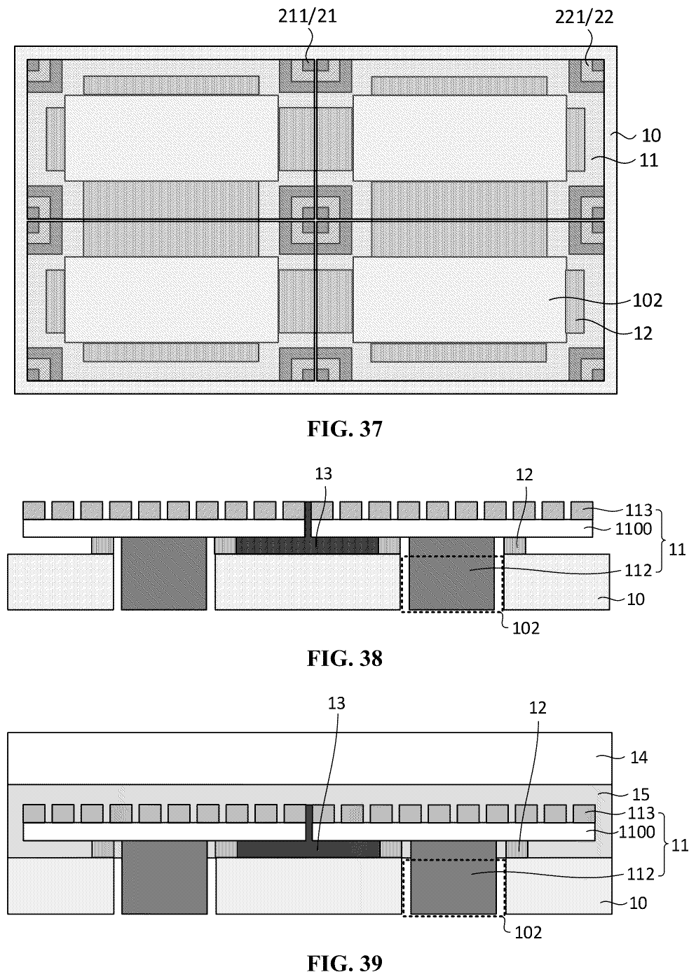

FIG. 37 is a diagram illustrating the structure of another tiled display panel according to an embodiment of the present disclosure. As shown in FIG. 37, in an embodiment, in the thickness direction of the display subpanel 11, the gaps between the adhesive 12 and the adjacent display subpanel 11 at least partially overlap, and the adhesive 12 is a black adhesive. With this disposition, the visibility of the tiling gap can be reduced, and it is ensured that the gaps are not apparent, thereby improving the tiled display effect.

It is to be noted that when the adhesive 12 is a black adhesive, in the thickness direction of the transparent substrate 10, the adhesive 12 does not overlap the first sub-pattern 211 and the second sub-pattern 221, so that the adhesive 12 is prevented from blocking the first sub-pattern 211 and the second sub-pattern 221 and affecting the alignment.

In other embodiments, if the adhesive 12 is a transparent structure, in the thickness direction of the transparent substrate 10, the adhesive 12 may overlap the first sub-pattern 211 and the second sub-pattern 221. Thus, it is beneficial to increase the set area of the adhesive 12 and improve the reliability of the adhesion and fixation between the transparent substrate 10 and the display subpanel 11.

FIG. 38 is a sectional view illustrating the structure of a tiled display panel according to an embodiment of the present disclosure. As shown in FIG. 38, in an embodiment, the tiled display panel further includes a light absorbing layer 13. In the thickness direction of the display subpanel 11, the gaps between the light absorbing layer 13 and the adjacent display subpanels 11 at least partially overlap, so that the visibility of the tiling gap can be reduced, and it is ensured that the gaps are not apparent, thereby improving the tiled display effect.

The light absorbing layer 13 may use black glue. The black glue is filled in the gap between adjacent display subpanels 11 to form the light absorbing layer 13. The process is simple and easy to implement. The black glue may be UV glue, which is not limited thereto.

FIG. 39 is a sectional view illustrating the structure of another tiled display panel according to an embodiment of the present disclosure. As shown in FIG. 39, the display subpanel 11 includes the base substrate 1100 and multiple sub-pixels 113 disposed on a side of the base substrate 1100. The tiled display panel further includes a cover plate 14. The cover plate 14 is located on the side of the sub-pixels 113 facing away from the base substrate 1100.

The cover plate 14 may be a glass plate to protect the display subpanel 11.

In some embodiments, the cover plate 14 may also be a one glass solution (OGS) to implement the touch function of the tiled display panel, which is not limited thereto. This is not limited in the embodiment of the present disclosure.

With continued reference to FIG. 39, the cover plate 14 and the display subpanel 11 may be adhered through an optical adhesive layer 15. The material of the optical adhesive layer 15 may use an optically clear adhesive (OCA) or an optical clear resin (OCR). The thickness of the optical adhesive layer 15 may be 200 μm to 500 μm. This is not limited in the embodiment of the present disclosure.

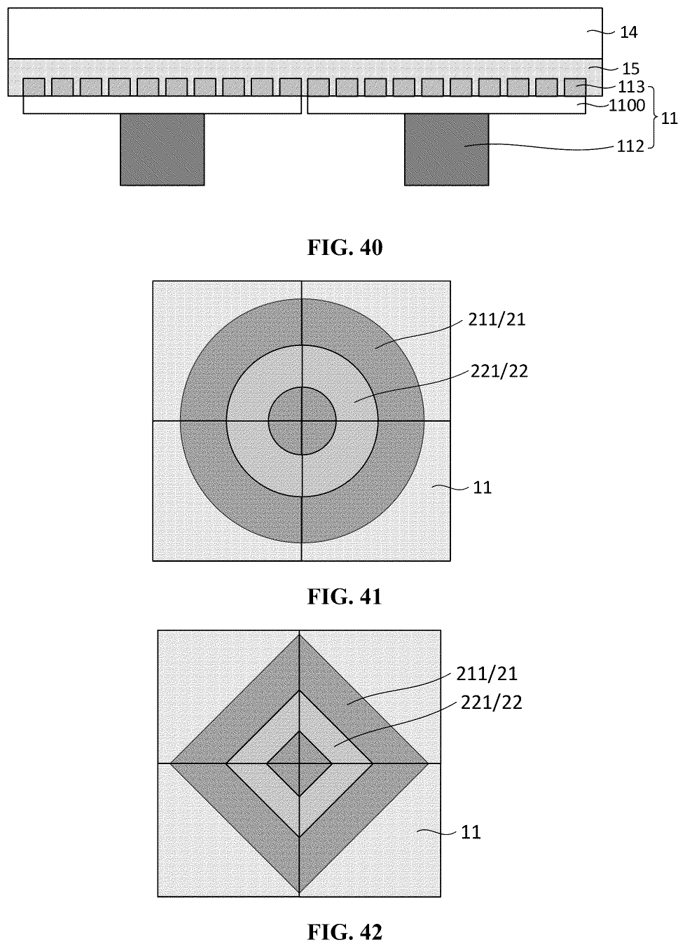

FIG. 40 is a sectional view illustrating the structure of another tiled display panel according to an embodiment of the present disclosure. As shown in FIG. 40, the display subpanel 11 is supported and fixed by the cover plate 14, and the transparent substrate may be removed. Thus, the thickness and weight of the tiled display panel are reduced, and a thin and light design is implemented. At the same time, the transparent substrate can be reused to reduce manufacturing costs.

It is to be noted that the shape of the first sub-pattern 211 on the transparent substrate 10 and the shape of the second sub-pattern 221 on the display subpanel 11 may be arbitrarily disposed according to actual requirements. For example, a regular graph may be split to form the first sub-pattern 211 on the transparent substrate 10 and the second sub-pattern 221 on the display subpanel 11. The regular graph may include a circle or a quadrilateral, which is not limited thereto.

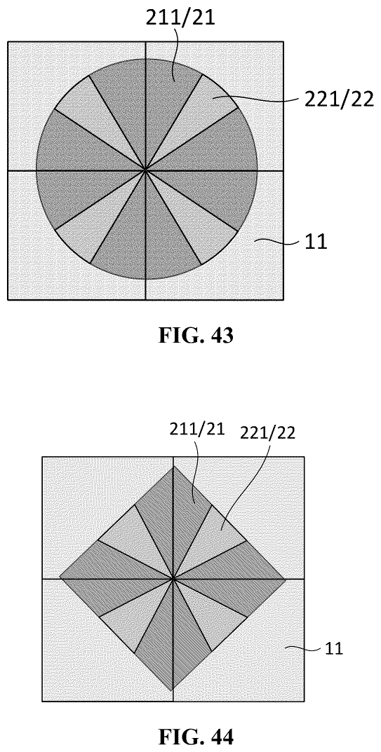

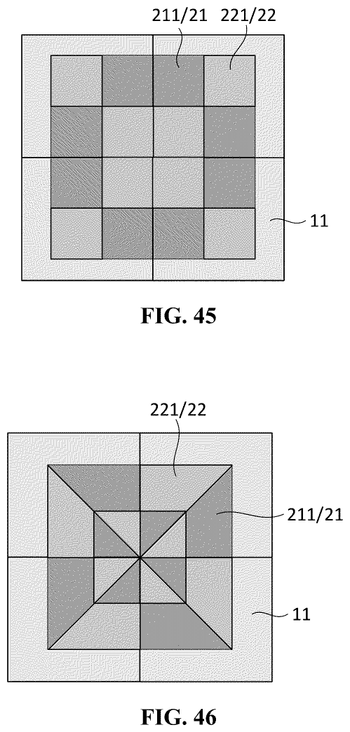

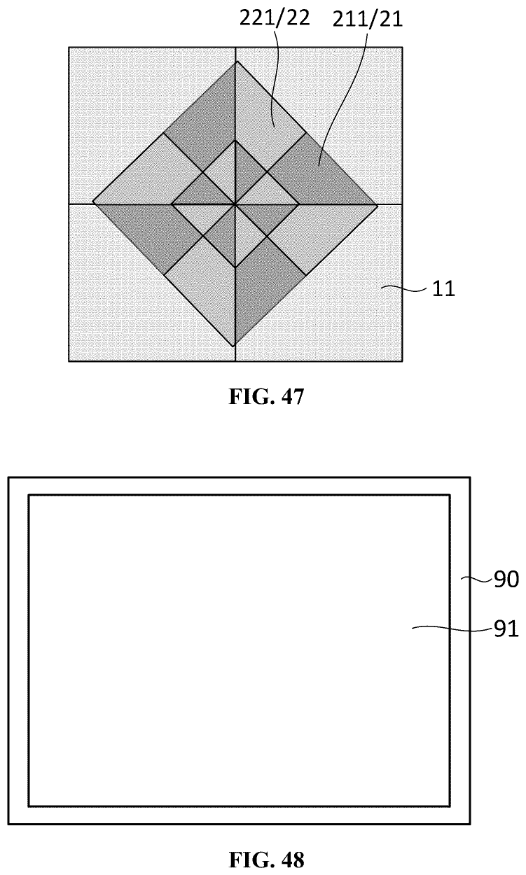

FIGS. 41 to 47 are partial views illustrating the structure of a tiled display panel according to an embodiment of the present disclosure. FIGS. 41 to 47 exemplarily show the combined shapes of some first sub-patterns 211 and second sub-patterns 221, which is not limited thereto. This is not limited in the embodiment of the present disclosure.

Based on the same inventive concept, embodiments of the present disclosure further provide a display device. FIG. 48 is a diagram illustrating the structure of a display device according to an embodiment of the present disclosure. As shown in FIG. 48, the display device 90 includes the display panel 91 according to any embodiment of the present disclosure. Thus, the display device 90 provided in the embodiments of the present disclosure has the technical effects of the technical solution of any one of the embodiments described above, and structures which are the same as or correspond to the structures in the embodiments described above and the explanation of the term will not be repeated herein.

The display device 90 provided by the embodiments of the present disclosure may be any electronic product having a display function. This is not limited in this embodiment of the present disclosure.

The preceding embodiments do not limit the scope of the present disclosure. It is to be understood by those skilled in the art that various modifications, combinations, sub-combinations, and substitutions may be performed according to design requirements and other factors. Any modifications, equivalent substitutions, improvements and the like made within the spirit and principle of the present disclosure are within the scope of the present disclosure.

What is claimed is:

1. A tiled display panel, comprising a transparent substrate and at least two display subpanels, wherein
the transparent substrate comprises at least two tiled regions, and the at least two display subpanels are disposed in the at least two tiled regions respectively;
the transparent substrate further comprises a first alignment pattern, the first alignment pattern comprises at least two first sub-patterns, and the at least two first sub-patterns are disposed in the at least two tiled regions respectively;
a first sub-pattern of the at least two first sub-patterns comprises a hollowed-out region; and
a display subpanel of the at least two display subpanels comprises a second alignment pattern, the second alignment pattern comprises at least two second sub-patterns, a shape of a second sub-pattern of the at least two second sub-patterns is the same as a shape of the hollowed-out region, and a vertical projection of the second sub-pattern on the transparent substrate is located in the hollowed-out region.

2. The tiled display panel according to claim 1, wherein
the transparent substrate comprises at least two first alignment patterns, and the at least two first alignment patterns have a same shape.

3. The tiled display panel according to claim 2, wherein
the display subpanel comprises a first vertex angle region, a second vertex angle region, a third vertex angle region, and a fourth vertex angle region, the first vertex angle region and the third vertex angle region are disposed opposite to each other, and the second vertex angle region and the fourth vertex angle region are disposed opposite to each other;
the first vertex angle region and the third vertex angle region are provided with second sub-patterns of the at least two second sub-patterns, and a second sub-pattern in the third vertex angle region is rotated 180° relative to a second sub-pattern in the first vertex angle region; and/or
the second vertex angle region and the fourth vertex angle region are provided with second sub-patterns of the at least two second sub-patterns, and a second sub-pattern in the fourth vertex angle region is rotated 180° relative to a second sub-pattern in the second vertex angle region.

4. The tiled display panel according to claim 2, wherein
the display subpanel comprises a first vertex angle region, a second vertex angle region, a third vertex angle region, and a fourth vertex angle region arranged in a clockwise direction; and
the first vertex angle region, the second vertex angle region, the third vertex angle region, and the fourth vertex angle region are provided with second sub-patterns of the at least two second sub-patterns, and a second sub-pattern of the first vertex angle region, a second sub-pattern of the second vertex angle region, a second sub-pattern of the third vertex angle region, and a second sub-pattern of the fourth vertex angle region are rotated 90° clockwise in sequence.

5. The tiled display panel according to claim 2, wherein
an area of the first sub-pattern is greater than or equal to an area of the second sub-pattern.

6. The tiled display panel according to claim 1, wherein
the first sub-pattern comprises a first pattern subsection and a second pattern subsection; and
the vertical projection of the second sub-pattern on the transparent substrate is located between the first pattern subsection and the second pattern subsection.

7. The tiled display panel according to claim 1, wherein
the first sub-pattern comprises a first pattern subsection and a second pattern subsection; and the second sub-pattern comprises a third pattern subsection and a fourth pattern subsection; and
in a clockwise direction, the first pattern subsection, the third pattern subsection, the second pattern subsection, and the fourth pattern subsection are arranged in sequence.

8. The tiled display panel according to claim 1, wherein
a contour line of the second sub-pattern comprises a first straight line and a second straight line, and an extension direction of the first straight line is perpendicular to an extension direction of the second straight line.

9. The tiled display panel according to claim 8, wherein
the display subpanel comprises a first side and a second side, and an extension direction of the first side is perpendicular to an extension direction of the second side; and
the first straight line is parallel to the first side, and the second straight line is parallel to the second side.

10. The tiled display panel according to claim 1, wherein
the at least two tiled regions comprise a first tiled region and a second tiled region, the at least two display subpanels comprise a first display subpanel and a second display subpanel, the first display subpanel is correspondingly disposed in the first tiled region, and the second display subpanel is correspondingly disposed in the second tiled region;
a first sub-pattern in the first tiled region is a first pattern, and a first sub-pattern in the second tiled region is a second pattern;
a second sub-pattern on the first display subpanel is a third pattern, and a second sub-pattern on the second display subpanel is a fourth pattern; and
the first pattern and the fourth pattern have a same shape, and the second pattern and the third pattern have a same shape.

11. The tiled display panel according to claim 10, wherein
the first display subpanel and the second display subpanel are arranged in a first direction, and the first display subpanel and the second display subpanel are arranged in a second direction; and
the first direction intersects with the second direction.

12. The tiled display panel according to claim 1, wherein
in the at least two tiled regions, the at least two first sub-patterns comprise a first pattern and a second pattern;
in the at least two display subpanels, the at least two second sub-patterns comprise a third pattern and a fourth pattern;
a vertical projection of the third pattern on the transparent substrate is located in a hollowed-out region of the first pattern, and a vertical projection of the fourth pattern on the transparent substrate is located in a hollowed-out region of the second pattern; and
the first pattern and the fourth pattern have a same shape, and the second pattern and the third pattern have a same shape.

13. The tiled display panel according to claim 12, wherein
in the at least two display subpanels, the third pattern and the fourth pattern are arranged in a third direction, and the third pattern and the fourth pattern are arranged in a fourth direction; and
the third direction intersects with the fourth direction.

14. The tiled display panel according to claim 10, wherein
an area of a first pattern is different from an area of a third pattern, and an area of a second pattern is different from an area of a fourth pattern.

15. The tiled display panel according to claim 1, wherein
the tiled display panel comprises a vertex angle region and a middle region;
the at least two display subpanels comprise a third display subpanel and a fourth display subpanel, a vertical projection of the third display subpanel on the tiled display panel is located in the vertex angle region, and a vertical projection of the fourth display subpanel on the tiled display panel is located in the middle region; and
a number of second sub-patterns on the third display subpanel is greater than a number of second sub-patterns on the fourth display subpanel.

16. The tiled display panel according to claim 1, wherein
the tiled display panel comprises a central region and a periphery region surrounding the central region;
the at least two display subpanels comprise a fifth display subpanel and a sixth display subpanel, a vertical projection of the fifth display subpanel on the transparent substrate is located in the central region, and a vertical projection of the sixth display subpanel on the transparent substrate is located in the periphery region; and
a number of second sub-patterns on the fifth display subpanel is greater than a number of second sub-patterns on the sixth display subpanel.

17. The tiled display panel according to claim 1, wherein
the display subpanel comprises a base substrate, a driver structure, and a plurality of sub-pixels, and the driver structure is located on a side of the base substrate facing away from the plurality of sub-pixels;
the transparent substrate comprises at least two openings, and the at least two openings are disposed in the at least two tiled regions respectively; and
a vertical projection of the driver structure on the transparent substrate is located in an opening of the at least two openings.

18. The tiled display panel according to claim 1, wherein
the at least two display subpanels comprise a seventh display subpanel and an eighth display subpanel, and the seventh display subpanel and the eighth display subpanel are disposed adjacent to each other;
an arrangement direction of the seventh display subpanel and the eighth display subpanel is a fifth direction; and
the seventh display subpanel and the eighth display subpanel are arranged in a staggered manner in a sixth direction, wherein the sixth direction intersects with the fifth direction.

19. The tiled display panel according to claim 1, wherein
an adhesive is further disposed on the transparent substrate, and the adhesive is located between the transparent substrate and the display subpanel; and
the adhesive comprises an ultraviolet viscose reduction adhesive.

20. A display device, comprising a tiled display panel, wherein the tiled display panel comprises a transparent substrate and at least two display subpanels, wherein
the transparent substrate comprises at least two tiled regions, and the at least two display subpanels are disposed in the at least two tiled regions respectively;
the transparent substrate further comprises a first alignment pattern, the first alignment pattern comprises at least two first sub-patterns, and the at least two first sub-patterns are disposed in the at least two tiled regions respectively;
a first sub-pattern of the at least two first sub-patterns comprises a hollowed-out region; and
a display subpanel of the at least two display subpanels comprises a second alignment pattern, the second alignment pattern comprises at least two second sub-patterns, a shape of a second sub-pattern of the at least two second sub-patterns is the same as a shape of the hollowed-out region, and a vertical projection of the second sub-pattern on the transparent substrate is located in the hollowed-out region.
